(19) United States
(12) Patent Application Publication
(10) Pub. No.: US 2026/0229293 A1
(43) Pub. Date: Aug. 6, 2026

(54) SEMICONDUCTOR DEVICE AND MEMORY SYSTEM

(71) Applicant: Kioxia Corporation, Tokyo (JP)

(72) Inventors: Shouichi OZAKI, Komae Tokyo (JP); Harumi ABE, Kawasaki Kanagawa (JP); Reiji ARIYOSHI, Yamato Kanagawa (JP); Kenro KUBOTA, Fujisawa Kanagawa (JP); Akito FURUYA, Kamakura Kanagawa (JP); Noriyuki MORIYASU, Kawasaki Kanagawa (JP); Terufumi TAKASAKI, Yokohama Kanagawa (JP); Kento NAKAMURA, Yokohama Kanagawa (JP)

(21) Appl. No.: 19/323,676

(22) Filed: Sep. 9, 2025

(30) Foreign Application Priority Data
Feb. 4, 2025 (JP) 2025-016630

(51) Int. Cl. G11C 16/30; G11C 5/14; G11C 16/26

(52) U.S. Cl. CPC G11C 16/30; G11C 5/147; G11C 16/26

(57) ABSTRACT

A semiconductor device includes a first voltage line to which a first voltage is supplied, a second voltage line to which a second voltage and a first current corresponding to the second voltage are supplied, a third voltage line to which a second current corresponding to a third voltage is supplied, a fourth voltage line to which a fourth voltage is supplied, a reference voltage line to which a reference voltage is supplied, a first voltage generation circuit configured to generate the third voltage and the second current, a second voltage generation circuit configured to generate the fourth voltage, a memory unit, an interface circuit, and an internal circuit. The semiconductor device is electrically connected to a control circuit configured to adjust the ratio between the first current and the second current.

### CROSS-REFERENCE TO RELATED APPLICATION(S)

This application is based upon and claims the benefit of priority from Japanese Patent Application No. 2025-016630, filed on Feb. 4, 2025, the entire contents of which are incorporated herein by reference.

### FIELD

Embodiments described herein relate generally to a semiconductor device. In addition, embodiments described herein relate generally to a memory system.

### BACKGROUND

A three-dimensional NAND flash memory, which is a type of semiconductor device, is known. A memory system including such a semiconductor memory device is also known.

### BRIEF DESCRIPTION OF THE DRAWINGS

FIG. 1 is a block diagram illustrating an overview of a memory system including a semiconductor memory device according to a first embodiment.

FIG. 2 is a plan view showing an example circuit configuration of the memory system including the semiconductor memory device according to the first embodiment.

FIG. 3 is a plan view showing an example circuit configuration of the semiconductor memory device according to the first embodiment.

FIG. 4 is a flowchart illustrating an example method of operating the memory system according to the first embodiment.

FIG. 5 is a plan view showing a modification of the memory system including the semiconductor memory device according to the first embodiment.

FIG. 6 is a block diagram illustrating an overview of a memory system including a semiconductor memory device according to a second embodiment.

FIG. 7 is a plan view showing an example circuit configuration of the memory system including the semiconductor memory device according to the second embodiment.

FIG. 8 is a plan view showing a modification of the memory system including the semiconductor memory device according to the second embodiment.

FIG. 9 is a plan view illustrating an example of voltage stabilization in the memory system including the semiconductor memory device according to the second embodiment.

### DETAILED DESCRIPTION

Embodiments provide a semiconductor device which includes a first voltage line and a second voltage line to which voltages are supplied, and which includes a configuration capable of adjusting a ratio between a first current corresponding to the voltage supplied to the first voltage line and a second current corresponding to the voltage supplied to the second voltage line. Further, a memory system is provided, which includes a first voltage line and a second voltage line to which voltages are supplied, and which includes a configuration capable of adjusting a ratio between a first current corresponding to the voltage supplied to the first voltage line and a second current corresponding to the voltage supplied to the second voltage line.

In general, according to one embodiment, a semiconductor device includes a first voltage line to which a first voltage is supplied, a second voltage line to which a second voltage lower than the first voltage and a first current corresponding to the second voltage are supplied, a third voltage line to which a third voltage and a second current corresponding to the third voltage are supplied, a fourth voltage line to which a fourth voltage higher than the second voltage and lower than the first voltage is supplied, a reference voltage line to which a reference voltage that is lower than the second voltage and serves as a reference is supplied, a first voltage generation circuit electrically connected to the first voltage line, the third voltage line, and the reference voltage line, and configured to generate the third voltage and the second current, a second voltage generation circuit electrically connected to the first voltage line, the fourth voltage line, and the reference voltage line, and configured to generate the fourth voltage, a memory unit electrically connected to the first voltage line and the reference voltage line, an interface circuit electrically connected to the second voltage line, the third voltage line, and the reference voltage line, and an internal circuit electrically connected to the fourth voltage line, the reference voltage line, the interface circuit, and the memory unit, and the semiconductor device is electrically connected to a control circuit configured to adjust a ratio between the first current supplied to the second voltage line and the second current supplied to the third voltage line.

According to one embodiment, a memory system includes a plurality of semiconductor devices each including a first voltage line to which a first voltage is supplied, a second voltage line to which a second voltage lower than the first voltage and a first current corresponding to the second voltage are supplied, a third voltage line to which a third voltage and a second current corresponding to the third voltage are supplied, a fourth voltage line to which a fourth voltage higher than the second voltage and lower than the first voltage is supplied, a reference voltage line to which a reference voltage that is lower than the second voltage and serves as a reference is supplied, a first voltage generation circuit electrically connected to the first voltage line, the third voltage line, and the reference voltage line, and configured to generate the third voltage and the second current, a second voltage generation circuit electrically connected to the first voltage line, the fourth voltage line, and the reference voltage line, and configured to generate the fourth voltage, a memory unit electrically connected to the first voltage line and the reference voltage line, an interface circuit electrically connected to the second voltage line, the third voltage line, and the reference voltage line, and an internal circuit electrically connected to the fourth voltage line, the reference voltage line, the interface circuit, and the memory unit, and a control circuit including a memory device storing a plurality of set values and a plurality of programs, and configured to adjust a ratio between the first current supplied to the second voltage line and the second current supplied to the third voltage line, in which the memory unit of each of the plurality of semiconductor devices includes a memory cell array including a plurality of blocks, and the plurality of set values include a first set value for setting activation or deactivation of the first voltage generation circuit, a plurality of second set values for setting the ratio, a third set value for setting at least one semiconductor device to be used among the plurality of semiconductor devices, and a fourth set value for setting at least one block to be used in the memory unit of the at least one semiconductor device to be used.

According to one embodiment, a memory system includes a first voltage line to which a first voltage is supplied, a second voltage line to which a second voltage lower than the first voltage is supplied, a third voltage line to which a third voltage same as the second voltage is supplied, a fourth voltage line to which a fourth voltage lower than the third voltage is supplied, a reference voltage line to which a reference voltage that is lower than the fourth voltage and that serves as a reference is supplied, a control circuit including a first voltage generation circuit electrically connected to the first voltage line, the third voltage line, and the reference voltage line, and configured to generate the third voltage and a first current corresponding to the third voltage, a second voltage generation circuit electrically connected to the second voltage line, the fourth voltage line, and the reference voltage line, and configured to generate the fourth voltage, a first internal circuit electrically connected to the second voltage line and the reference voltage line, and a first interface circuit electrically connected to the fourth voltage line, the reference voltage line, and the first internal circuit, and a semiconductor device including a third voltage generation circuit electrically connected to the first voltage line, the third voltage line, and the reference voltage line, and configured to generate the third voltage and a second current corresponding to the third voltage, a memory unit electrically connected to the first voltage line and the reference voltage line, a second internal circuit electrically connected to the third voltage line and the reference voltage line, and a second interface circuit electrically connected to the fourth voltage line, the reference voltage line, the second internal circuit, and the first interface circuit, in which the control circuit is configured to adjust a ratio between the first voltage supplied from the first voltage generation circuit to the third voltage line and the second voltage supplied from the third voltage generation circuit to the third voltage line and the second internal circuit.

Hereinafter, a semiconductor memory device and a memory system according to each embodiment will be described with reference to the drawings. In the following description, elements having the same or similar functions and configurations are denoted by common reference numerals. For example, when distinguishing a plurality of elements denoted by common reference numerals, those plurality of elements are distinguished by appending subscripts (e.g., uppercase alphabet letters, lowercase alphabet letters, numbers, or hyphens and uppercase alphabet letters with numbers) to the common reference numerals. In addition, if necessary, the same or similar elements may be described repeatedly, and descriptions of the same or similar elements may be omitted.

Each embodiment presented below illustrates an apparatus or a method for embodying the technical idea of each embodiment. The technical idea of each embodiment is not limited to the specific materials, shapes, structures, arrangements, and the like of the components described below. The technical idea of each embodiment may be modified in various ways within the scope of the claims.

When the terms “same” and “identical” are used in each embodiment illustrated below, the terms “same” and “identical” may include allowable variations within the design tolerance range.

### 1. First Embodiment

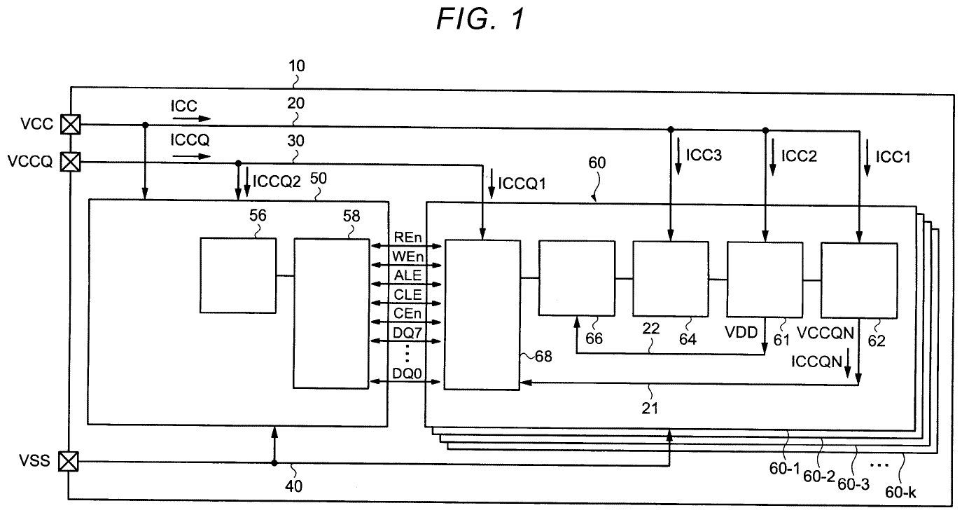

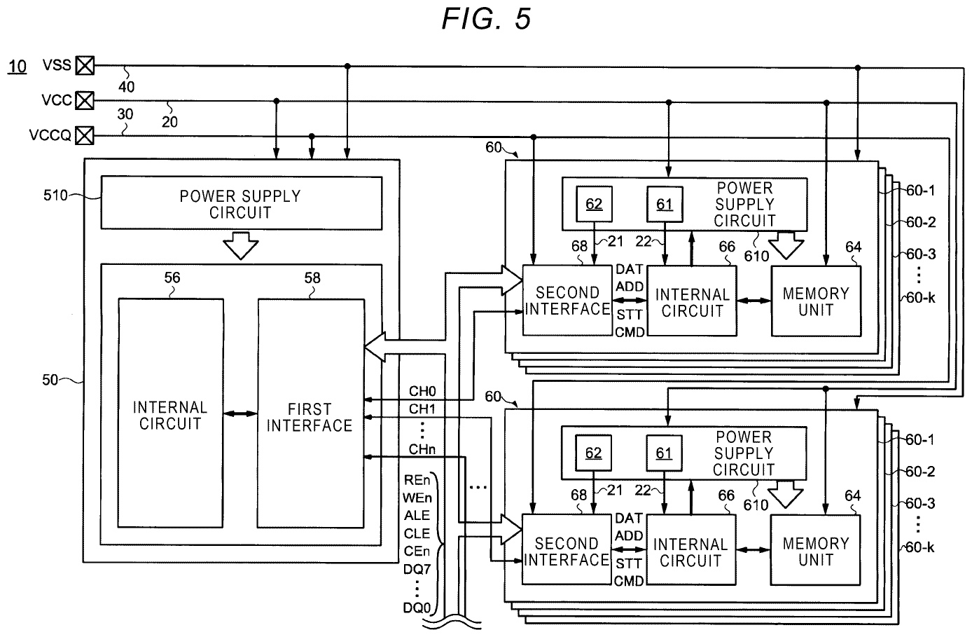

A semiconductor memory device 60 and a memory system 10 according to a first embodiment will be described with reference to FIGS. 1 to 4. In addition, modifications of the semiconductor memory device 60 and the memory system 10 according to the first embodiment will be described with reference to FIG. 5 and the like.

### 1-1. Overview of Semiconductor Memory Device 60

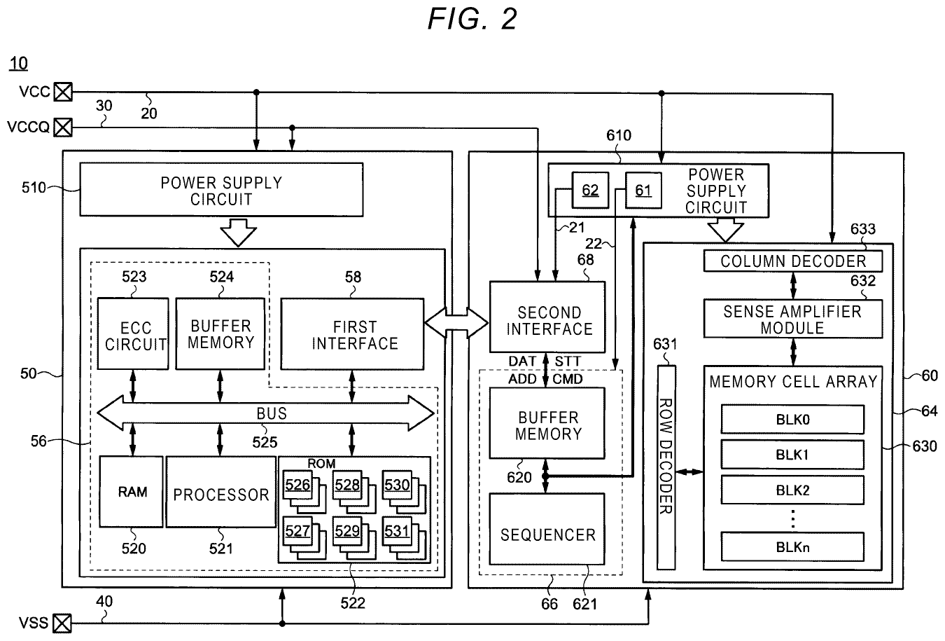

FIG. 1 is a block diagram illustrating an overview of the memory system 10 that includes the semiconductor memory device 60. FIG. 2 is a plan view illustrating an example circuit configuration of the memory system 10 that includes the semiconductor memory device 60.

As illustrated in FIGS. 1 and 2, the semiconductor memory device 60 includes a first voltage generation circuit 62, a second voltage generation circuit 61, a memory unit 64, a second interface circuit 68, and an internal circuit 66. In addition, the semiconductor memory device 60 includes a portion of a first voltage line 20 to which a voltage VCC is supplied, a portion of a second voltage line 30 to which a voltage VCCQ and a current ICCQ1 corresponding to the voltage VCCQ are supplied, a third voltage line 21 to which a voltage VCCQN and a current ICCQN corresponding to the voltage VCCQN are supplied, a fourth voltage line 22 to which a voltage VDD is supplied, and a portion of a reference voltage line 40 to which a voltage VSS serving as a reference voltage is supplied, and is electrically connected to the first voltage line 20, the second voltage line 30, and the voltage VSS serving as the reference voltage.

The second interface circuit 68 may be configured based on various interface specifications. For example, the second interface circuit 68 may be configured based on the interface specification known as Toggle Double Data Rate (toggle DDR), and may be configured based on the ONFI (Open NAND Flash Interface, or ONFI) standards. For example, the interface technology based on the toggle DDR or the ONFI standards may include a DDR-based interface technology using both rising and falling edges of a reference signal, and functionality related to error correction code (ECC). For example, when the second interface circuit 68 includes a configuration based on the toggle DDR or a configuration based on the ONFI standards, the second interface circuit 68 improves resistance to signal noise and also improves the communication environment of the signal, thereby enabling faster data transfer. For example, the specifications of the toggle DDR and ONFI standards are available from the Joint Electron Device Engineering Councils (JEDEC) at https://www.jedec.org/category/keywords/toggle.

In the first embodiment, the voltage VCCQ is lower than the voltage VCC, the voltage VCCQN is the same as the voltage VCCQ, the voltage VDD is higher than the voltage VCCQ and lower than the voltage VCC, and the voltage VSS is lower than the second voltage VCCQ. For example, the voltage VCC is 2.5 V, the voltages VCCQ and VCCQN are 1.2 V, and the voltage VSS is 0 V or the ground voltage.

The current ICC corresponding to the voltage VCC includes a current ICC1, a current ICC2 and a current ICC3, and each of the current ICC1, the current ICC2 and the current ICC3 is a current corresponding to the voltage VCC. Further, the current ICCQ corresponding to the voltage VCCQ includes a current ICCQ1 and a current ICCQ2, and each of the current ICCQ1 and the current ICCQ2 is a current corresponding to the voltage VCCQ.

The first voltage generation circuit 62 is electrically connected to the first voltage line 20, the third voltage line 21, and the reference voltage line 40. The first voltage generation circuit 62 is configured to receive the voltage VCC and the current ICC1 and to generate the voltage VCCQN and the current ICCQN.

The second voltage generation circuit 61 is electrically connected to the first voltage line 20, the fourth voltage line 22, and the reference voltage line 40. The second voltage generation circuit 61 is configured to receive the voltage VCC and the current ICC2 and to generate the voltage VDD.

The memory unit 64 is electrically connected to the second voltage generation circuit 61, the internal circuit 66, the first voltage line 20 and the reference voltage line 40, and receives the voltage VCC and the current ICC3.

The second interface circuit 68 is electrically connected to the internal circuit 66, the second voltage line 30, the third voltage line 21, and the reference voltage line 40.

The internal circuit 66 is electrically connected to the fourth voltage line 22 and the reference voltage line 40.

In addition, the semiconductor memory device 60 is electrically connected to a memory controller 50 (also referred to as a control circuit). Details will be described below, but for example, the memory controller 50 is configured to adjust the ratio between the current ICCQ1 supplied to the second voltage line 30 and the current ICCQN supplied to the third voltage line 21.

A conventional semiconductor memory device has a configuration in which the current ICCQ1 and the current ICCQN are fixed in the design stage of the semiconductor memory device, and the ratio between the current ICCQ1 and the current ICCQN in the conventional semiconductor memory device is not variable. Accordingly, in the conventional semiconductor memory device, the ratio between the current ICCQ1 and the current ICCQN cannot be adjusted after design. As a result, the conventional semiconductor memory devices are customized in accordance with the specifications and applications of the semiconductor memory devices, which reduces their versatility as semiconductor memory devices.

On the other hand, the semiconductor memory device 60 is configured to adjust the ratio between the current ICCQ1 supplied to the second voltage line 30 and the current ICCQN supplied to the third voltage line 21. Accordingly, the semiconductor memory device 60 can adjust the ratio between the current ICCQ1 and the current ICCQN after design. As a result, the semiconductor memory device 60 can be adjusted according to the specifications and applications of the semiconductor memory device and has high versatility as the semiconductor memory device.

### 1-2. Example of Circuit Configuration of Semiconductor Memory Device 60

As illustrated in FIG. 2, the semiconductor memory device 60 includes the second interface circuit 68, a power supply circuit 610, the internal circuit 66, and the memory unit 64.

Although not shown, the second interface circuit 68 includes a plurality of input and output terminals, an input and output circuit electrically connected to the plurality of input and output terminals, and a logic control circuit. The second interface circuit 68 is electrically connected to the memory controller 50 and the internal circuit 66.

The input and output circuit controls input and output of a signal DQ to an external device such as the memory controller 50, which controls the semiconductor memory device 60. For example, the signal DQ is a signal that includes 8-bit data from signal DQ0 to signal DQ7. Although not shown, the input and output circuit includes an input circuit, an output circuit, and a logic control circuit.

For example, the input circuit transmits data DAT such as write data received from an external device to a data register in a buffer memory 620, transmits an address ADD to an address register in the buffer memory 620, and transmits a command CMD to a command register in the buffer memory 620. For example, the output circuit transmits data DAT such as read data received from the data register in the buffer memory 620 and the address ADD received from the address register in the buffer memory 620 to the external device.

For example, the logic control circuit receives, from the memory controller 50, a control signal for controlling the semiconductor memory device 60, such as a chip enable signal CEn, a command latch enable signal CLE, an address latch enable signal ALE, a write enable signal WEn, and a read enable signal REn. The logic control circuit controls the input and output circuit and a sequencer 621 based on the received signal.

The chip enable signal CEn is a signal for enabling the semiconductor memory device 60. The command latch enable signal CLE is a signal for notifying the second interface circuit 68 that the signal DQ input to the semiconductor memory device 60 is the command CMD. The address latch enable signal ALE is a signal for notifying the second interface circuit 68 that the signal DQ input to the semiconductor memory device 60 is the address information ADD.

The write enable signal WEn is a signal for indicating that it is inputting a signal into the semiconductor memory device 60, and is asserted each time the command CMD, the address ADD and the data DAT are received by the memory controller 50. For example, the memory controller 50 instructs the semiconductor memory device 60 to receive signals DQ0 to DQ7 while the signal WEn is at a low level. Alternatively, memory controller 50 may instruct the semiconductor memory device 60 to receive the signals DQ0 to DQ7 while the signal WEn is at a high level. For example, the high level indicates a voltage with a high voltage, the low level indicates a voltage with a low voltage, and the high level has a higher voltage than the low level.

The read enable signal REn is a signal for the memory controller 50 to indicate that it is reading data from the semiconductor memory device 60. For example, the read enable signal REn is used to control the operation timing of the semiconductor memory device 60 when it is outputting the signals DQ0 to DQ7.

For example, the power supply circuit 610 generates the voltage VCCQN and the voltage VDD using the first voltage generation circuit 62 and the second voltage generation circuit 61, generates voltages other than the voltage VCCQN and the voltage VDD required for write operation, read operation, and erase operation in accordance with the control of the sequencer 621, and supplies the generated voltages to the internal circuit 66, a memory cell array 630, a row decoder 631, a column decoder 633, a sense amplifier module 632, and the like. For example, the row decoder 631 and the sense amplifier module 632 may supply the voltage supplied from the power supply circuit 610 to each memory cell in the memory cell array 630.

For example, the internal circuit 66 includes the buffer memory 620 and the sequencer 621.

Although not shown, the buffer memory 620 includes various registers such as a status register, an address register, a command register, and a data register. For example, the status register has a function of temporarily storing status information STT during write, read, and erase operations, and notifying an external device whether the operation is normally completed via the input and output circuit. For example, the address register temporarily stores the address ADD received from the external device via the input and output circuit. In addition, the address register transfers a row address to the row decoder 631, and transfers a column address to the column decoder 633. The command register temporarily stores the command CMD received from the external device via the input and output circuit and transfers it to the sequencer 621.

The sequencer 621 controls the overall operation of the semiconductor memory device 60. For example, the sequencer 621 controls the status register, the power supply circuit 610, the row decoder 631, the sense amplifier module 632, the data register, the column decoder 633, and the like according to the command CMD transferred from the command register to control the execution of the write operation, the read operation, the erase operation, and the like.

The memory unit 64 includes the memory cell array 630, the row decoder 631, the sense amplifier module 632, and the column decoder 633, which will be described in detail below.

### 1-3. Configuration of Memory Unit 64

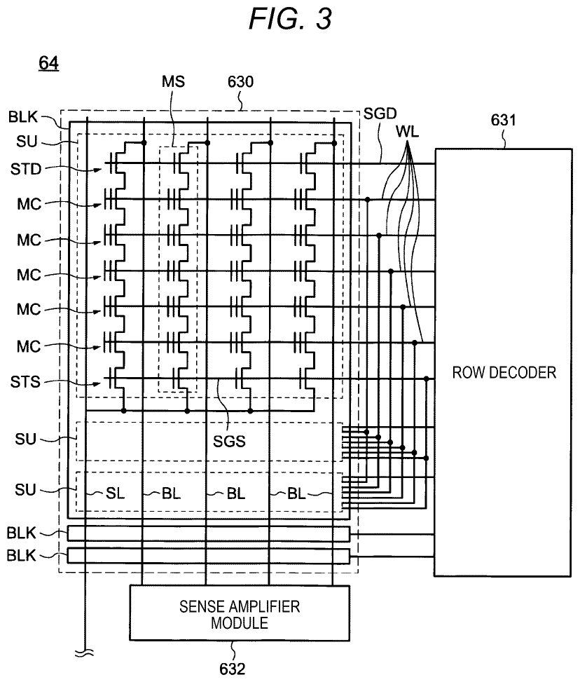

FIG. 3 is a plan view illustrating an example circuit configuration of the memory unit 64 of the semiconductor memory device 60.

As illustrated in FIGS. 2 and 3, the memory cell array 630 includes a plurality of blocks BLK (BLK0, BLK1, BLK2, . . . , BLKn). The number n is an integer greater than or equal to 2. Each of the blocks BLK is a collection of a plurality of memory cells associated with a bit line and a word line. For example, the blocks BLK are each an erasure unit of data. For example, the memory cell is a charge-storing transistor that stores data in a non-volatile manner by storing electric charge. For example, the semiconductor memory device 60 includes such memory cells and operates as a NAND nonvolatile memory.

The row decoder 631 decodes the row address. The row decoder 631 selects one of the plurality of blocks BLK based on the result of decoding. The row decoder 631 supplies voltages necessary for the write operation, the read operation, and the erase operation to each block BLK.

For example, in the read operation, the sense amplifier module 632 determines data read from the memory cell array 630. In addition, in the read operation, the sense amplifier module 632 transmits the read data to the data register in the buffer memory 620.

Further, in the write operation, the sense amplifier module 632 transmits the write data to the memory cell array 630.

In addition, although now shown, the data register in the buffer memory 620 includes a plurality of latch circuits. The latch circuit stores the write data and the read data. For example, in the write operation, the data register in the buffer memory 620 temporarily stores the write data received from the input and output circuit and transmits it to the sense amplifier module 632. In the read operation, the data register in the buffer memory 620 temporarily stores the read data received from the sense amplifier module 632 and transmits it to the input and output circuit.

For example, the column decoder 633 decodes a column address during the write operation, the read operation, and the erase operation, and selects a latch circuit in the data register in the buffer memory 620 according to the result of the decoding.

As described above, the memory cell array 630 includes the plurality of blocks BLK. As illustrated in FIG. 3, each of the plurality of blocks BLK includes a plurality of string units SU. Each of the plurality of string units SU includes a plurality of memory strings MS. Each end of the plurality of memory strings MS is electrically connected to the sense amplifier module 632, the column decoder 633, and the like via a bit line BL. Each other end of the plurality of memory strings MS is electrically connected to a common source line SL.

A memory string MS is provided between the bit line BL and the source line SL. The memory string MS includes a drain select transistor STD, a plurality of memory cells MC, and a source select transistor STS connected in series between the bit line BL and the source line SL. The drain select transistor STD and the source select transistor STS may be described as select transistors STD and STS.

The memory cell MC is, for example, a field effect transistor (FET) that includes a charge storage layer in a gate insulation layer. A threshold voltage of the memory cell MC varies according to the amount of charge stored in the charge storage layer. By providing one or a plurality of threshold voltages, the memory cell MC may store one or a plurality of bits of data. A word line WL is connected to each gate terminal of the plurality of memory cells MC corresponding to one memory string MS. Each of these word lines WL is connected to a plurality of (or all) memory strings MS in one block BLK in common.

The select transistors STD and STS are, for example, field-effect transistors. Select gate lines SGD and SGS are connected to gate terminals of the select transistors STD and STS, respectively. The select gate line SGD connected to the drain select transistor STD is provided per string unit SU and is connected in common to the plurality of (or all) memory strings MS in one string unit SU. The select gate line SGS connected to the source select transistor STS is connected in common to the plurality of (or all) memory strings MS in one block BLK.

For example, each end of the word line WL and the select gate lines SGD and SGS is electrically connected to the row decoder 631.

Although not shown, the memory unit 64 may include a plurality of stacked memory cell arrays 630.

### 1-4. Overview of Memory System 10

The memory system 10 is an example system in which the semiconductor memory device 60 is mounted. As illustrated in FIGS. 1 and 2, the memory system 10 includes the first voltage line 20 to which the voltage VCC is supplied, the second voltage line 30 to which the voltage VCCQ and the current ICCQ2 corresponding to the voltage VCCQ are supplied, the reference voltage line 40 to which the voltage VSS serving as a reference is supplied, the memory controller 50, and a plurality of semiconductor memory devices 60. For example, each of the semiconductor memory device 60 and the memory controller 50 is formed as a semiconductor chip. The semiconductor chip may simply be referred to as a chip.

The memory system 10 may be connected to a host (not illustrated). For example, the memory system 10 is a solid state drive (SSD), a memory card such as a SD™ card, or the like. For example, the host is an electronic device, such as a personal computer and a portable terminal. The memory system 10 may include the host. The memory system 10 includes the plurality of semiconductor memory devices 60 (60-1 to 60-k (where, k is a positive integer)), but in FIG. 1, only one semiconductor memory device 60-1 out of the plurality of semiconductor memory devices 60 (60-1 to 60-k) is illustrated as being electrically connected to each voltage line, and the electrical connections between each of the semiconductor memory devices 60-2 to 60-k other than the semiconductor memory device 60-1 and each voltage line are omitted in FIG. 1. Further, the memory system 10 includes the plurality of semiconductor memory devices 60 (60-1 to 60-k), but to facilitate understanding of the memory system 10, in the following description of the memory system 10, the plurality of semiconductor memory devices 60 (60-1 to 60-k) will be collectively referred to as the semiconductor memory device 60, and when necessary, as the plurality of semiconductor memory devices 60 (60-1 to 60-k).

### 1-5. Configuration of Memory Controller 50

For example, the memory controller 50 transmits the command CMD according to a program necessary for the operation of the semiconductor memory device 60 to the semiconductor memory device 60. In addition, the memory controller 50 transmits the command CMD, the control signal, and the like according to the program to the semiconductor memory device 60, and controls the data read operation from the semiconductor memory device 60, the data write operation to the semiconductor memory device 60, and the data erase operation of the semiconductor memory device 60.

As described in “1-2. Example of circuit configuration of semiconductor memory device 60”, respective signals, such as the chip enable signal CEn, the command latch enable signal CLE, the address latch enable signal ALE, the write enable signal WEn, the read enable signal REn, and the signals DQ0 to DQ7, are transmitted and received between the memory controller 50 and the semiconductor memory device 60.

As illustrated in FIG. 1 or FIG. 2, the memory controller 50 includes a power supply circuit 510, an internal circuit 56, and a first interface circuit 58.

For example, the power supply circuit 510 is electrically connected to the first voltage line 20, the third voltage line 21, and the reference voltage line 40, generates voltages necessary for the operation of the internal circuit 56 and the first interface circuit 58 using the voltage VCC, the voltage VCCQ and the voltage VSS, and supplies the generated voltages to the internal circuit 56 and the first interface circuit 58. The power supply circuit 510 may supply the generated voltage to the semiconductor memory device 60, as necessary.

For example, as illustrated in FIG. 2, the internal circuit 56 includes a random access memory (RAM) 520, a read-only memory (ROM) 522, an error checking and correction (ECC) circuit 523, a processor 521, a buffer memory 524, and an internal bus 525. The RAM 520, the processor 521, the ROM 522, the ECC circuit 523, the buffer memory 524, and the first interface circuit 58 are electrically connected to each other through the internal bus 525.

Based on the command CMD from the processor 521, the first interface circuit 58 controls the write operation of writing the data DAT or the like to the semiconductor memory device 60, the read operation of reading the data DAT or the like from the semiconductor memory device 60, the erase operation of erasing the data DAT stored in the semiconductor memory device 60, and the transfer of the data temporarily stored in the buffer memory 524.

Although the illustration is omitted, for example, the memory system 10 may include a host interface for outputting requests (requests, instructions), data (e.g., write data), and the like received from the host to the internal bus 525. Further, for example, the host interface may transmit data (read data) read from the semiconductor memory device 60, signals including responses from the processor 521, and the like to the host. The host interface is electrically connected to the host.

For example, the host interface may be configured based on the Universal Flash Storage (UFS) standards. For example, the UFS is a type of memory device commonly used in digital cameras, portable information terminals, flash memory storage for home appliances, and the like, and can read and write data faster and more efficiently than related technologies such as Embedded Multi Media Card (eMMC). For example, the UFS standard is a standard related to improving the data transfer speed and reliability of the memory device and eliminating the need to change the adapter for each type of card. For example, additional information on the UFS standards is available from the Joint Electron Device Engineering Councils (JEDEC) at https://www.jedec.org/standards-documents/focus/flash/universal-flash-storage-ufs.

The RAM 520 is used as a work area for the processor 521. In addition, the RAM 520 stores various management tables or the like. For example, the various management tables include management tables for managing correspondence between addresses (e.g., logical addresses) received from the host and physical locations (e.g., physical addresses) in the semiconductor memory device 60 and pointing to physical locations of pages to be used next. For example, the RAM 520 is a general-purpose memory such as a static random access memory(SRAM) and a dynamic random access memory(DRAM). It is to be noted that the RAM 520 may be allocated as the buffer memory 524.

For example, the ROM 522 includes a first area 526 storing a first set value for setting activation or deactivation of the first voltage generation circuit 62, a second area 527 storing a plurality of second set values for setting the ratio between a current ICCQ1 supplied to the second voltage line 30 and a current ICCQN supplied to the third voltage line 21, a third area 528 storing a plurality of third set values for setting at least one semiconductor memory device 60 to be used among the plurality of semiconductor memory devices 60, a fourth area 529 storing a plurality of fourth set values for setting at least one memory cell array 630 to be used or at least one block BLK to be used in the memory unit 64 of at least one semiconductor memory device 60 to be used, a fifth area 530 storing a fifth set value for setting a value of current to be consumed by the semiconductor memory device 60 (current consumption value), setting the activation or deactivation of the first voltage generation circuit 62, and adjusting the ratio between the current ICCQ1 supplied to the second voltage line 30 and the current ICCQN supplied to the third voltage line 21 according to the operation state of the memory system 10 or the semiconductor memory device 60, and a sixth area 531 storing values corresponding to each command used by the processor 521.

The ECC circuit 523 encodes the data stored in the RAM 520 to generate a codeword. Further, the ECC circuit 523 decodes the codeword read from the semiconductor memory device 60. As an example, the memory system 10 illustrated in FIG. 1 includes the memory controller 50 that includes the ECC circuit 523 and the first interface circuit 58. Meanwhile, the memory system 10 is not limited to the example illustrated in FIG. 1. For example, the memory system 10 may include the ECC circuit 523 embedded in the first interface circuit 58 and may include the ECC circuit 523 embedded in the semiconductor memory device 60.

The processor 521 controls the memory controller 50. For example, the processor 521 includes an arithmetic processing circuit such as a Central Processing Unit (CPU) and a Micro Processing Unit (MPU). For example, the processor 521 controls the memory controller 50 and the semiconductor memory device 60 based on a control program corresponding to a command of the memory controller 50. In addition, for example, when the processor 521 receives a request from the host via the host interface, the processor 521 performs control in accordance with the request.

In addition, the processor 521 is configured to load the firmware (e.g., control program) stored in the sixth area 531 of the ROM 522 onto the RAM 520 to execute a predetermined process. As a result, for example, the processor 521 can control generating various management tables in the RAM 520, accessing the semiconductor memory device 60 based on a command for executing a write operation, a command for executing a read operation, or a command for executing an erase operation, and processing the transfer of data temporarily stored in the buffer memory 524.

In addition, the processor 521 may instruct the first interface circuit 58 to perform the write operation of data (e.g., user data) and parity to the semiconductor memory device 60 in response to a request received from the host, and may instruct the first interface circuit 58 to perform the read operation of data and parity from the semiconductor memory device 60 in response to a request received from the host.

In addition, the processor 521 sets a storage area (also referred to as a memory area) on the semiconductor memory device 60 for the data stored in the RAM 520. Data is stored in the RAM 520 via the internal bus 525. The processor 521 performs setting of a memory area for data in page units, which are write units. For example, the data in page units is page data, and the capacity of the data in page units is 16 kB. For example, the data stored on one page of the semiconductor memory device 60 is defined as unit data. In general, the unit data is encoded by the ECC circuit 523, and stored in the semiconductor memory device 60 as a codeword. Although the configuration of the memory system 10 illustrated in FIG. 1 illustrates a configuration for encoding as an example, encoding is optional in the memory system 10. For example, the memory controller 50 may store the unit data in the semiconductor memory device 60 without performing encoding. When the memory controller 50 does not perform encoding, the page data matches the unit data. Further, one codeword may be generated based on one unit data, or one codeword may be generated based on divided data that is split from the unit data. Further, one codeword may be generated using a plurality of unit data.

Further, the processor 521 sets a memory area of the semiconductor memory device 60 as a write destination for each unit data. A physical address is assigned to the memory area of the semiconductor memory device 60. The processor 521 manages the memory area as the write destination of the unit data using the physical address. The processor 521 designates the determined memory area of the semiconductor memory device 60 (hereinafter referred to as physical address) and instructs the first interface circuit 58 to write data to the semiconductor memory device 60. The processor 521 manages the correspondence between the logical address (logical address managed by the host) of the data and the physical address. When the processor 521 receives a read request including a logical address from the host, the processor 521 identifies a physical address corresponding to the logical address, and instructs the first interface circuit 58 to read the data by designating the physical address.

For example, the buffer memory 524 has a function of temporarily storing data or the like received from the host before storing it in the semiconductor memory device 60, and temporarily storing data read from the semiconductor memory device 60 before transmitting it to the host. For example, the buffer memory 524 is a general-purpose memory such as a static random access memory (SRAM).

Here, the operation of the memory controller 50 is briefly described.

For example, when the memory controller 50 receives a write request from the host, the memory controller 50 is operated as follows. The processor 521 temporarily stores data as the write target in the RAM 520. The processor 521 reads the data stored in the RAM 520 and inputs the read data to the ECC circuit 523. The ECC circuit 523 encodes the input data and inputs the codeword to the first interface circuit 58. The first interface circuit 58 writes the input codeword to the semiconductor memory device 60.

For example, when the memory controller 50 receives a read request from the host, the memory controller 50 is operated as follows. The first interface circuit 58 inputs the codeword read from the semiconductor memory device 60 to the ECC circuit 523. The ECC circuit 523 decodes the input codeword and stores the decoded data in the RAM 520. The processor 521 transmits the data stored in the RAM 520 to the host via the host interface.

### 1-6. Example of Method of Operating Memory System 10

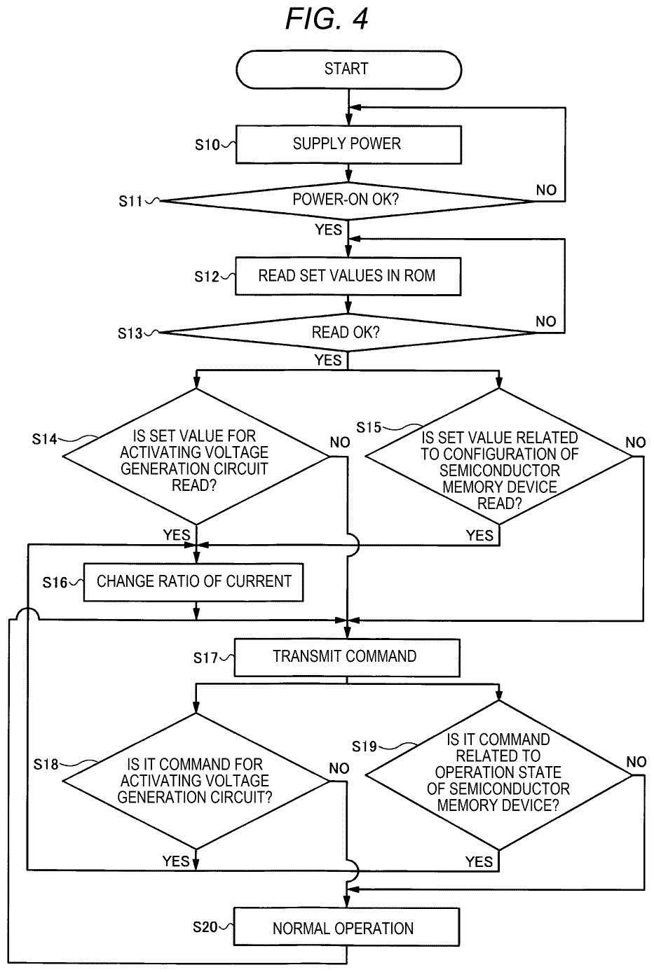

FIG. 4 is a flowchart illustrating an example method of operating the memory system 10. As illustrated in FIG. 4, the method of operating the memory system 10 includes steps 10 to 20 (S10 to S20).

When the operation of the memory system 10 starts, S10 is executed. S10 is a step of supplying power to the memory system 10. For example, an external device such as the host supplies power to the memory system 10. The voltage VCC is supplied to the first voltage line 20, the voltage VCCQ and the current ICCQ1 corresponding to the voltage VCCQ are supplied to the second voltage line 30, and the voltage VSS is supplied to the reference voltage line 40.

Step 11 (S11) is a step of verifying power-on of the power (power-on OK?). For example, S11 is a step of verifying that power is supplied to the memory system 10 and that the memory system 10 is in an operational state.

For example, when power is supplied to the memory system 10 (power is on, YES in S11), the processor 521 executes the process of step 12 (S12). When power is not supplied to the memory system 10 (NO in S11), the process returns to S10 and until power is supplied to the memory system 10.

S12 is a step of reading set values in the ROM 522. For example, the processor 521 reads into the RAM 520 the first set value to the fifth set value stored in the first area 526 to the fifth area 530 in the ROM 522 according to the specifications and applications of the memory system 10 or the semiconductor memory device 60. The processor 521 may read the first set value and the second set value stored in the first area 526 and the second area 527 in the ROM 522 into the RAM 520, may read the first set value to the third set value stored in the first area 526 to the third area 528 in the ROM 522 into the RAM 520, may read the first set value to the fourth set value stored in the first area 526 to the fourth area 529 in the ROM 522 into the RAM 520, and may read the first set value, the second set value and the fifth set value stored in the first area 526, the second area 527 and the fifth area 530 in the ROM 522 into the RAM 520.

Step 13 (S13) is a step of verifying whether reading of the set values in the ROM 522 is performed normally (read OK?). For example, as a result of the verification by the processor 521, when the processor 521 can normally read the set values in the ROM 522 into the RAM 520 (YES in S13), the processor 521 executes the processes of steps 14 and 15 (S14 and S15). As a result of the verification by the processor 521, when the processor 521 cannot normally read the set values in the ROM 522 to the RAM 520 (NO in S13), the process returns to S12 and the memory system 10 is controlled so that step 12 (S12) is repeated.

After the step of S13, the memory system 10 executes the step of S14 and the step of S15 in parallel.

For example, S14 is a step of verifying whether a set value for activating the voltage generation circuit is read out and verifying whether to change the current ratio. In S14, the processor 521 verifies whether the first set value read from the first area 526 of the ROM 522 is a set value for activating the first voltage generation circuit 62, and also verifies whether the second set value read from the second area 527 of the ROM 522 is a set value that includes the ratio between the current ICCQ1 and the current ICCQN.

As a result of the verification in S14 by the processor 521, when the first set value is the set value for activating the first voltage generation circuit 62 and the second set value is the set value that includes the ratio between the current ICCQ1 and the current ICCQN (YES in S14), the processor 521 executes the process of step 16 (S16). As a result of the verification in S14 by the processor 521, when the first set value is a set value for not activating the first voltage generation circuit 62 or the second set value does not include the ratio between the current ICCQ1 and the current ICCQN (NO in S14), the processor 521 executes the process of step 17 (S17).

In addition, for example, in S14, the processor 521 may verify whether the fifth set value read from the fifth area 530 of the ROM 522 is a set value for setting a value of current consumed by the semiconductor memory device 60 (current consumption value), for setting the activation or deactivation of the first voltage generation circuit 62, and for adjusting the ratio between the current ICCQ1 supplied to the second voltage line 30 and the current ICCQN supplied to the third voltage line 21. Further, the fifth set value is a set value corresponding to the operation state of the memory system 10 or the semiconductor memory device 60. In addition, for example, as a result of the verification in S14 by the processor 521, when the fifth set value is set (NO in S14), the processor 521 executes the process of S17.

For example, S15 is a step of verifying whether the set value related to the configuration of the semiconductor memory device 60 is read out and whether to change the current ratio. Here, the configuration of the semiconductor memory device 60 may correspond to one or more of configurations 1 to 3 illustrated below.
(Configuration 1) The plurality of semiconductor memory devices 60-1 to 60-k
(Configuration 2) The plurality of memory cell arrays 630 stacked in the memory unit 64
(Configuration 3) The plurality of blocks BLK in the memory cell array 630

In S15, the processor 521 verifies whether the first set value read from the first area 526 of the ROM 522 is the set value for activating the first voltage generation circuit 62, verifies whether the second set value read from the second area 527 of the ROM 522 is the set value that includes the ratio between the current ICCQ1 and the current ICCQN, and verifies whether the third set value read from the third area 528 of the ROM 522 is a set value for setting at least one semiconductor memory device to be used among the plurality of semiconductor memory devices 60-1 to 60-k. In addition, in S15, the processor 521 may verify whether the first set value read from the first area 526 of the ROM 522 is the set value for activating the first voltage generation circuit 62, verify whether the second set value read from the second area 527 of the ROM 522 is the set value that includes the ratio between the current ICCQ1 and the current ICCQN, verify whether the third set value read from the third area 528 of the ROM 522 is the set value for setting at least one semiconductor memory device to be used among the plurality of semiconductor memory devices 60-1 to 60-k, and verify whether the fourth set value read from the fourth area 529 of the ROM 522 is a set value for setting at least one memory cell array 630 to be used or at least one block BLK to be used in the memory unit 64 of the at least one semiconductor memory device to be used that is set by the third set value. It is to be noted that the first set value and the second set value in S15 are set values according to the configuration of the semiconductor memory device 60.

For example, as a result of the verification by the processor 521, when the first set value is the set value for activating the first voltage generation circuit 62, the second set value is the set value that includes the ratio between the current ICCQ1 and the current ICCQN, and the third set value is the set value for setting at least one semiconductor memory device to be used among the plurality of semiconductor memory devices 60-1 to 60-k (YES in S15), the processor 521 executes the process of S16. For example, as a result of the verification by the processor 521, when the first set value is the set value for activating the first voltage generation circuit 62, the second set value is the set value that includes the ratio between the current ICCQ1 and the current ICCQN, the third set value is the set value for setting at least one semiconductor memory device to be used among the plurality of semiconductor memory devices 60-1 to 60-k, and the fourth set value is the set value for setting at least one memory cell array 630 to be used or at least one block BLK to be used in the memory unit 64 of the at least one semiconductor memory device to be used that is set by the third set value (YES in S15), the processor 521 executes the process of S16. As a result of the verification by the processor 521, when the third set value is a set value that does not set at least one semiconductor memory device to be used out of the plurality of semiconductor memory devices 60-1 to 60-k (NO in S15), the processor 521 executes the process of S17. It is to be noted that when the third set value is not set, the fourth set value is not set either.

S16 is a step of changing the current ratio.

For example, when S16 is based on the first set value and the second set value set in S14, in S16, the processor 521 changes the ratio between the current ICCQ1 and the current ICCQN based on the first set value and the second set value set in S14. For example, when the first set value is the set value for activating the first voltage generation circuit 62 and the second set value is a set value for setting the ratio between the current ICCQ1 and the current ICCQN to X:Y, the processor 521 reads and loads into the RAM 520 a first program, from among the plurality of programs stored in the sixth area 531, which includes activating (using) the first voltage generation circuit 62 and setting the ratio between the current ICCQ1 and the current ICCQN to X:Y, and generates a first command based on the first program. The numerical values X and Y are expressed as percentages such that X+Y=100%, and any numerical value may be used as long as X+Y=100%. The second area 527 in the ROM 522 stores a plurality of second set values such that X+Y=100%. For example, when X is 50%, Y is 50%, and when X is 20%, Y is 80%.

In addition, for example, when S16 is based on the first set value and the second set value set in S15, the processor 521 in S16 changes the ratio between the current ICCQ1 and the current ICCQN based on the first set value, the second set value, and the third set value set in S15, or based on the first set value, the second set value, the third set value, and the fourth set value set in S15. For example, the first set value and the second set value set in S15 are similar to the first set value and the second set value “when S16 is based on the first set value and the second set value set in S14”. For example, the third set value is the set value for setting at least one semiconductor memory device to be used among the plurality of semiconductor memory devices 60-1 to 60-k, and the fourth set value is the set value for setting at least one memory cell array 630 to be used or at least one block BLK to be used in the memory unit 64 of the at least one semiconductor memory device to be used that is set by the third set value. For example, the processor 521 reads and loads into the RAM 520 a second program, from among the plurality of programs stored in the sixth area 531, which includes activating (using) the first voltage generation circuit 62, setting the ratio between the current ICCQ1 and the current ICCQN to X:Y, and selecting at least one semiconductor memory device to be used from among the plurality of semiconductor memory devices 60-1 to 60-k, and generates a second command based on the second program. Further, for example, the processor 521 reads and loads into the RAM 520 a third program from among the plurality of programs stored in the sixth area 531, which includes activating (using) the first voltage generation circuit 62, setting the ratio between the current ICCQ1 and the current ICCQN to X:Y, selecting at least one semiconductor memory device to be used from among the plurality of semiconductor memory devices 60-1 to 60-k, and selecting at least one memory cell array 630 to be used or at least one block BLK to be used in the memory unit 64 of at least one semiconductor memory device to be used, and generates a third command based on the third program.

S17 is a step of transmitting a command.

For example, when the memory system 10 executes the processes of S14 and S16, and when the memory system 10 executes the processes of S15 and S16, in S17, the processor 521 transmits the data, the address signal, the command generated in S16 (e.g., the first command, the second command, or the third command), and various control signals temporarily stored in the buffer memory 524 to the first interface circuit 58 via the internal bus 525, and the first interface circuit 58 transmits the data, the address signal, the first command, the second command or the third command, and the various control signals to the semiconductor memory device 60 (in particular, the second interface circuit 68).

For example, when the memory system 10 executes the processes according to NO in S14, in S17, the first set value is the set value that includes not activating the first voltage generation circuit 62, and the second set value is the set value that includes the ratio of 1:0 (100% and 0%) between the current ICCQ1 corresponding to the voltage VCCQ and the second current ICCQN corresponding to the voltage VCCQN. That is, the current ICCQ1 corresponding to the voltage VCCQ accounts for 100% of the ratio. At this time, the processor 521 reads and loads into the RAM 520 a fourth program that includes that the first voltage generation circuit 62 is not activated and that the current ICCQ1 corresponding to the voltage VCCQ accounts for 100% of the ratio, and generates a fourth command based on the fourth program. The processor 521 transmits the data, the address signal, the command (e.g., the fourth command), and various control signals temporarily stored in the buffer memory 524 to the first interface circuit 58 via the internal bus 525, and the first interface circuit 58 transmits the data, the address signal, the fourth command, and the various control signals to the semiconductor memory device 60 (in particular, the second interface circuit 68).

In addition, for example, in S17, when the memory system 10 executes the processes according to NO in S14, the processor 521 reads and loads into the RAM 520 a fifth program based on the fifth set value, and generates a fifth command based on the fifth program. The processor 521 transmits the data, the address signal, the command (e.g., the fifth command), and various control signals temporarily stored in the buffer memory 524 to the first interface circuit 58 via the internal bus 525, and the first interface circuit 58 transmits the data, the address signal, the fifth command, and the various control signals to the semiconductor memory device 60 (in particular, the second interface circuit 68).

In addition, for example, in S17, when the memory system 10 executes the processes according to NO in S15, the processor 521 reads and loads into the RAM 520 a sixth program that includes not setting at least one semiconductor memory device to be used among the plurality of semiconductor memory devices 60-1 to 60-k, and generates a sixth command based on the sixth program. The processor 521 transmits the data, the address signal, the command (e.g., the sixth command), and various control signals temporarily stored in the buffer memory 524 to the first interface circuit 58 via the internal bus 525, and the first interface circuit 58 transmits the data, the address signal, the sixth command, and the various control signals to the semiconductor memory device 60 (in particular, the second interface circuit 68).

The memory system 10 executes the process of step 18 (S18) and process of step 19 (S19) in parallel after the process of S17.

In S18 and S19, when the second interface circuit 68 receives the data (data DAT), the address signal (address ADD), the command (command CMD) and the various control signals from the first interface circuit 58, the second interface circuit 68 transmits the data (data DAT), the address signal (address ADD), the command (command CMD) and the various control signals to the buffer memory 620 in the internal circuit 66. In addition, the sequencer 621 receives a command from the buffer memory 620 and controls the semiconductor memory device 60 in accordance with the received command.

For example, S18 is a step of verifying whether the command activates the voltage generation circuit. In addition, when the command activates the voltage generation circuit, the step involves operating the semiconductor memory device 60 based on the command.

In S18, the sequencer 621 receives a command from the buffer memory 620, verifies (determines) whether the command activates the voltage generation circuit, and controls the semiconductor memory device 60 in accordance with the received command.

For example, when the second interface circuit 68 receives one of the first command, the second command or the third command, the sequencer 621 verifies (determines) that the command is a command to activate the voltage generation circuit, activates the first voltage generation circuit 62 based on the command, and controls the semiconductor memory device 60 so that the semiconductor memory device 60 is operated at the set ratio between the current ICCQ1 and the current ICCQN. In addition, when the second interface circuit 68 receives one of the first command, the second command, and the third command (YES in S18), the memory system 10 repeatedly executes S16, S17 and S18.

In addition, for example, when the second interface circuit 68 receives one of the fourth command and the sixth command, the sequencer 621 executes the process of S20 when it verifies (determines) that the command is not a command to activate the voltage generation circuit (NO in S18).

For example, S19 is a step of verifying whether the command is related to the operation state of the semiconductor memory device 60. When the command is related to the operation state of the semiconductor memory device 60, the step involves operating the semiconductor memory device 60 based on the command.

In S19, the sequencer 621 receives a command from the buffer memory 620, verifies (determines) whether the command is related to the operation state of the semiconductor memory device 60, and controls the semiconductor memory device 60 in accordance with the received command.

For example, when the second interface circuit 68 receives the fifth command, the sequencer 621 verifies (determines) that the fifth command is a command related to the operation state of the semiconductor memory device 60 (YES in S19), and the memory system 10 controls so that the processes of S16, S17, and S18 are executed. For example, in S19, the sequencer 621 detects a value of current consumed by the semiconductor memory device 60 based on the fifth command, sets the activation or deactivation of the first voltage generation circuit 62 according to the detected current value, and stores the detected current value in the buffer memory 620 so as to adjust the ratio between the current ICCQ1 supplied to the second voltage line 30 and the current ICCQN supplied to the third voltage line 21. In S16 following S19, the sequencer 621 reads the current value stored in the buffer memory 620 and transmits the read value to the memory controller 50 (in particular, the first interface circuit 58) via the second interface circuit 68. Further, in S16 following S19, the first interface circuit 58 receives the current value and stores the current value in the buffer memory 524 via the internal bus 525. For example, the processor 521 reads the current value from the buffer memory 524 into the RAM 520 based on the fifth command, and by referring to the table in the RAM 520, reads, from the second area 527 in the ROM 520 into the buffer memory 524, the first set value for setting the activation or deactivation of the first voltage generation circuit 62 according to the current value, and the second set value corresponding to the ratio between the current ICCQ1 and the current ICCQN. At this time, the processor 521 may read the third set value or the fourth set value from the third area 528 or the fourth area 529 into the buffer memory 524. In addition, for example, in S16 following S19, the processor 521 reads and loads into the RAM 520 a seventh program, from among the plurality of programs stored in the sixth area 531, which includes activating (using) the first voltage generation circuit 62, setting the ratio between the current ICCQ1 to the current ICCQN to X:Y, setting the activation or deactivation of the first voltage generation circuit 62, and adjusting the ratio between the current ICCQ1 supplied to the second voltage line 30 and the current ICCQN supplied to the third voltage line 21, and generates a seventh command based on the seventh program. At this time, when the third set value or the fourth set value is stored in the buffer memory 524, the processor 521 may read and load into the RAM 520 an eighth program that incorporates a program based on the third set value or the fourth set value into the content of the seventh program, and may generate an eighth command based on the eighth program. In addition, for example, in S17 following S19 and S16, the processor 521 transmits the data, the address signal, the seventh command, and various control signals temporarily stored in the buffer memory 524 to the first interface circuit 58 via the internal bus 525, and the first interface circuit 58 transmits the data, the address signal, the command (e.g., the seventh command or the eighth command), and the various control signals to the semiconductor memory device 60 (in particular, the second interface circuit 68). The seventh command or the eighth command is a command based on the first set value and the second set value, and in S18, which follows S19, S16 and S17, the second interface circuit 68 receives the seventh command or the eighth command, and the sequencer 621 verifies (determines) that the seventh command or the eighth command is a command to activate the voltage generation circuit, activates or deactivates the first voltage generation circuit 62 based on the seventh command, adjusts the ratio between the current ICCQ1 and the current ICCQN to the ratio between the current ICCQ1 and the current ICCQN set in the seventh command, and controls the semiconductor memory device 60 so that the semiconductor memory device 60 is operated accordingly.

In S19, when verifying (determining) that the command received by the sequencer 621 is not a command related to the operation state of the semiconductor memory device 60 (NO in S19), the sequencer 621 executes the process of the S20.

S20 is a step of executing a normal operation. If NO in S18 and S19, the sequencer 621 controls the semiconductor memory device 60 to be operated normally. For example, the normal operation is an operation in which the first voltage generation circuit 62 is deactivated and not used, and the second voltage VCCQ and the current ICCQ1 supplied to the second voltage line are supplied to the second interface circuit 68.

For example, the memory system 10 including the semiconductor memory device 60 is configured to set the ratio between the current ICCQ1 supplied to the second voltage line 30 and the current ICCQN supplied to the third voltage line 21 in accordance with the first set value to the fifth set value using the method of operating described in “1-6. Example of method of operating memory system 10”. Furthermore, for example, the memory system 10 including the semiconductor memory device 60 is configured to adjust the ratio between the current ICCQ1 supplied to the second voltage line 30 and the current ICCQN supplied to the third voltage line 21 in accordance with the configuration of the semiconductor memory device 60 or the operation state of the semiconductor memory device 60, using the method of operating described in “1-6. Example of method of operating memory system 10”. As a result, the semiconductor memory device 60 can be adjusted according to the specifications and applications of the semiconductor memory device and has high versatility as the semiconductor memory device.

### 1-7. Modification of Memory System 10

FIG. 5 is a plan view illustrating a system according to a modification of the memory system 10 including the semiconductor memory device 60. For example, the system according to the modification of the memory system 10 including the semiconductor memory device 60 will be referred to as a modified memory system 10. The modified memory system 10 includes a plurality of sets of semiconductor memory devices 60, with the plurality of semiconductor memory devices 60-1 to 60-k in the memory system 10 being one set of semiconductor memory device. The other configurations and functions of the modified memory system 10 are similar to the configurations and functions of the memory system 10. Therefore, in “1-7. Modification of memory system 10”, contents related to the plurality of sets of semiconductor memory devices 60 will be primarily described, and description of contents identical or similar to the configurations and functions of the memory system 10 may be omitted.

As illustrated in FIG. 5, the modified memory system 10 includes a configuration in which the first interface circuit 58 in the memory controller 50 is electrically connected to the plurality of sets of semiconductor memory devices 60 to transmit and receive data to and from the plurality of sets of semiconductor memory devices 60.

For example, the first interface circuit 58 includes a plurality of channels CH0 to CHn (n is a positive integer). Each of the plurality of sets of semiconductor memory devices 60 is electrically connected to each channel. In the modified memory system 10 illustrated in FIG. 5, the plurality of sets of semiconductor memory devices 60 are connected to each of channels CH0 and CH1, and illustration of electrical connection between the channels CH2 to CHn and the plurality of sets of semiconductor memory devices 60 is omitted.

For example, when operating the modified memory system 10, the third set value includes a set value for at least one channel from among the plurality of channels CH0 to CHn, and one semiconductor memory device 60 in the at least one channel. At least one channel and at least one semiconductor memory device 60 to be used are selected in accordance with the third set value, and processes such as writing the data, reading the data and erasing the data are executed on the selected semiconductor memory device 60.

For example, during a write operation of the modified memory system 10, the memory controller 50 reads, from the first area 526 to the third area 528 in the ROM 522 into the RAM 520, the first set value, the second set value, and the third set value described above based on a request from the host, and reads, from the sixth area in the ROM 522 into the RAM 520, a control program (e.g., the second program) for executing the write operation issued by the processor 521. At this time, the control program (e.g., the second program) is a program that corresponds to the first set value, the second set value, and the third set value described above based on the first set value, the second set value, and the third set value described above. In addition, the processor 521 loads the control program into the RAM 520 and generates a command based on the control program. In addition, the processor 521 transmits the data, the address signals, the generated commands, and various control signals temporarily stored in the buffer memory 524 to the first interface circuit 58 via the internal bus 525, and the first interface circuit 58 transmits the write data, the address signals, the generated commands, and the various control signals read from the ROM 22 and temporarily stored in the buffer memory 524 to the selected semiconductor memory device 60.

At this time, since the third set value includes a set value for at least one channel of the plurality of channels CH0 to CHn and for one semiconductor memory device 60 in the at least one channel, the first interface circuit 58 transmits the write data, the address signal, the command, and the various control signals read from the ROM 22 and temporarily stored in the buffer memory 524 to the one semiconductor memory device 60 in at least one channel according to the third set value.

In addition, for example, during a read operation of the modified memory system 10, the memory controller 50 reads, from the first area 526 to the fourth area 529 in the ROM 522 into the RAM 520, the first set value, the second set value, and the third set value described above based on a request from the host, and reads, from the sixth area in the ROM 522 into the RAM 520, a control program (e.g., the second program) for executing the read operation issued by the processor 521. At this time, the control program is a program that corresponds to the first set value, the second set value, and the third set value described above based on the first set value, the second set value, and the third set value described above. In addition, the processor 521 loads the control program into the RAM 520 and generates a command based on the control program. In addition, the processor 521 transmits the address signal, the generated command, and various control signals to the first interface circuit 58 via the internal bus 525, and the first interface circuit 58 transmits the address signal, the generated command, and the various control signals to one semiconductor memory device 60 in at least one channel according to the third set value, and transmits and stores the read data received from the one semiconductor memory device 60 in the at least one channel according to the third set value in the buffer memory 524.

For example, the request from the host may include the fourth set value, and the fourth set value stored in the fourth area 529 in the ROM 522 may include a set value for at least one block BLK to be used in the memory unit 64 of one semiconductor memory device 60 in at least one channel.

Similar to the method of operating the memory system 10, the modified memory system 10 is operated using a flowchart similar to the flowchart illustrated in FIG. 4. As illustrated in FIG. 4, similar to the method of operating the memory system 10, the method of operating the modified memory system 10 includes steps 10 to 20 (S10 to S20). The method of operating the modified memory system 10 is applicable to when the memory system 10 described in “1-6. Example of method of operating memory system 10” is replaced with the modified memory system 10. It is to be noted that the method of operating the modified memory system 10 may be modified as appropriate in accordance with the configuration described in “1-7. Modified memory system 10”.

The configuration of the semiconductor memory device 60 in the modified memory system 10 may be illustrated as configurations 1 to 3, and as configuration 4 illustrated below.
(Configuration 4) The plurality of sets of semiconductor memory devices 60 electrically connected to at least one channel of the plurality of channels CH0 to CHn

Further, the operation state of the semiconductor memory device 60 in the modified memory system 10 includes the state of the plurality of sets of semiconductor memory devices 60 electrically connected to the plurality of channels CH0 to CHn, and the method of operating the modified memory system 10 includes controlling the ratio of currents supplied to the plurality of sets of semiconductor memory devices 60 electrically connected to the plurality of channels CH0 to CHn.

### 2. Second Embodiment

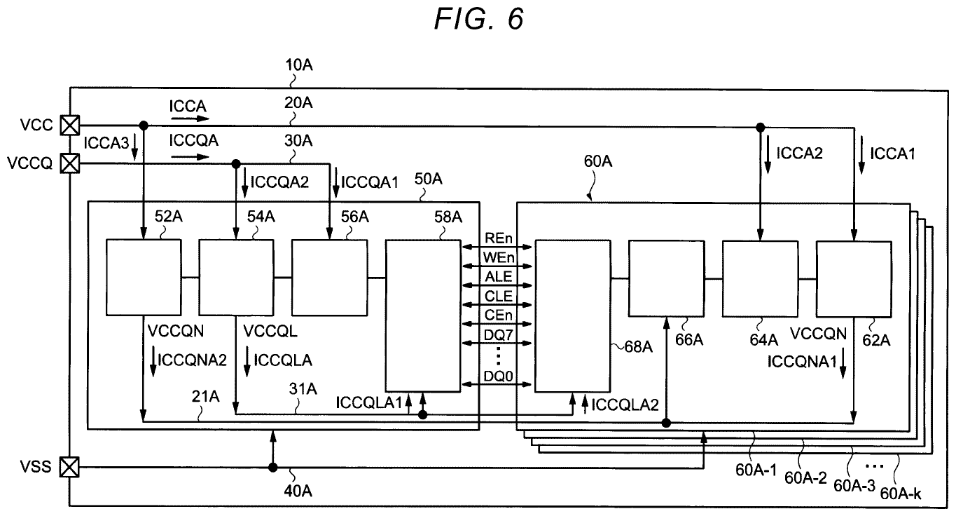

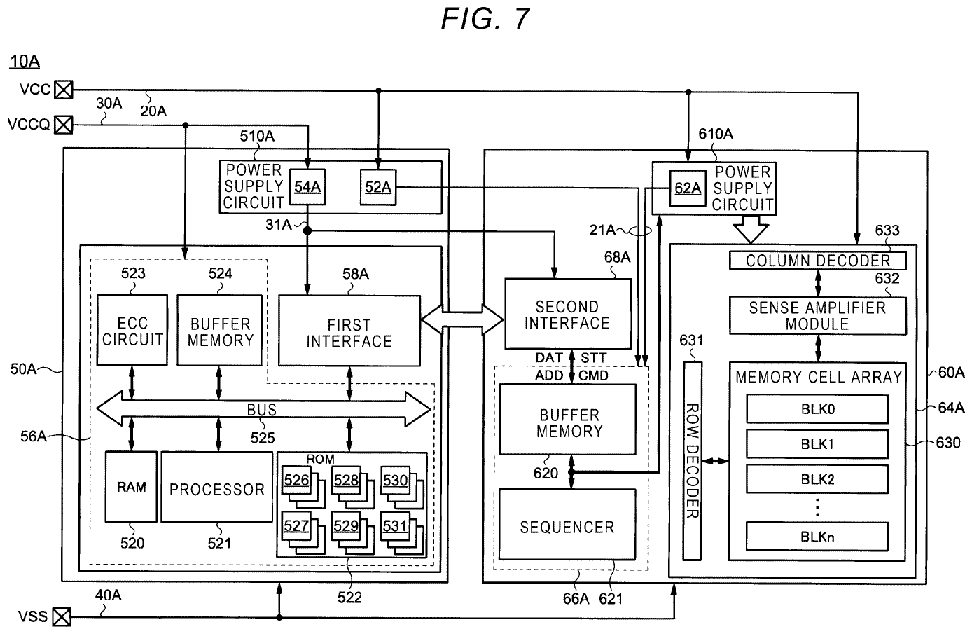

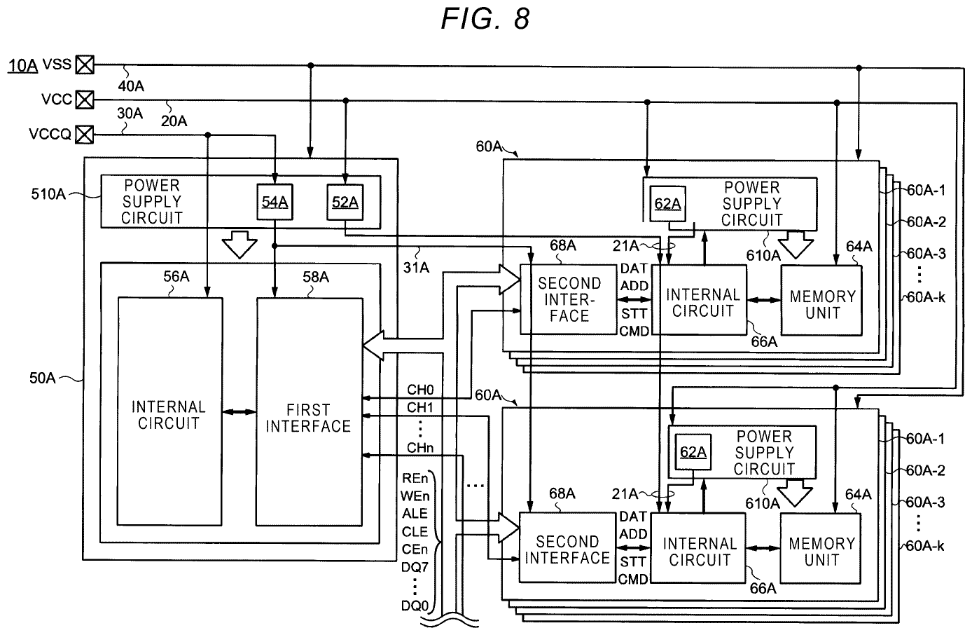

A memory system 10A according to the second embodiment will be described with reference to FIGS. 6 and 7. In addition, a modification of the memory system 10A according to the second embodiment will be described with reference to FIG. 8.

### 2-1. Overview of Memory System 10A

FIG. 6 is a block diagram illustrating an overview of the memory system 10A including a semiconductor memory device 60A. FIG. 7 is a plan view illustrating an example circuit configuration of the memory system 10A including the semiconductor memory device 60A.

As illustrated in FIG. 6 or FIG. 7, the memory system 10A includes a memory controller 50A and a plurality of semiconductor memory devices 60A. The memory system 10A also includes a first voltage line 20A to which the voltage VCC and a current ICCA corresponding to the voltage VCC are supplied, a second voltage line 30A to which the voltage VCCQ and a current ICCQA corresponding to the voltage VCCQ are supplied, a third voltage line 21A to which a current ICCQNA2 and a current ICCQNA1 corresponding to the voltage VCCQN are supplied, a fourth voltage line 31A to which the voltage VCCQL and a current ICQLA corresponding to the voltage VCCQL are supplied, and a reference voltage line 40A to which a voltage VSS serving as a reference voltage is supplied, and is electrically connected to the first voltage line 20A, the second voltage line 30A, and the reference voltage line 40A serving as the reference. For example, each of the semiconductor memory device 60A and the memory controller 50A is formed as a semiconductor chip. The semiconductor chip may simply be referred to as a chip.

In the second embodiment, voltage VCCQ is lower than the voltage VCC, the voltage VCCQN is the same as the voltage VCCQ, the voltage VCCQL is lower than the voltage VCCQ, and the voltage VSS is lower than the voltage VCCQL. For example, the voltage VCC is 2.5 V, the voltage VCCQ and the voltage VCCQN are 1.2 V, the voltage VCCQL is 0.6 V, and the voltage VSS is 0 V or the ground voltage.

The current ICCA corresponding to the voltage VCC includes a current ICCA1 and a current ICCA2, and each of the current ICCA1 and the current ICCA2 is a current corresponding to the voltage VCC. The current ICCQA corresponding to the voltage VCCQ includes a current ICCQA1 and a current ICCQA2, and each of the current ICCQA1 and the current ICCQA2 is a current corresponding to the voltage VCCQ. The current ICCQNA1 and the current ICCQNA2 are currents corresponding to the voltage VCCQN. The current ICCQL corresponding to the voltage VCCQL includes a current ICCQLA1 and a current ICCQLA2, and each of the current ICCQLA1 and the current ICCQLA2 is a current corresponding to the voltage VCCQL.

Similar to the memory system 10, the memory system 10A can be connected to a host (not illustrated). For example, similar to the memory system 10, the memory system 10A is a memory card such as a solid state drive (SSD) and an SD™ card. For example, the host is an electronic device such as a personal computer and a portable terminal. The memory system 10A may include a host. The memory system 10A includes the plurality of semiconductor memory devices 60A (60A-1 to 60A-k (where, k is a positive integer)) but in FIG. 6, only one semiconductor memory device 60A-1 of the plurality of semiconductor memory devices 60A (60A-1 to 60A-k) is illustrated as being electrically connected to each voltage line, and the electrical connections between each of the semiconductor memory devices 60A-2 to 60A-k other than the semiconductor memory device 60A-1 and each voltage line are omitted in FIG. 6. Further, the memory system 10A includes the plurality of semiconductor memory devices 60A (60A-1 to 60A-k), but to facilitate understanding of the memory system 10A, in the following description of the memory system 10A, the plurality of semiconductor memory devices 60A (60A-1 to 60A-k) will be collectively referred to as the semiconductor memory device 60A, and when necessary, as the plurality of semiconductor memory devices 60A (60A-1 to 60A-k).

A conventional memory system has a configuration in which the current ICCQNA1 and the current ICCQNA2 are fixed in the design stage of the memory system, and the ratio between the current ICCQNA1 and the current ICCQNA2 in the conventional memory system is not variable. Accordingly, the ratio between the current ICCQNA1 and the current ICCQNA2 in the conventional memory system cannot be adjusted after design. As a result, the conventional memory system is customized in accordance with the specifications and applications of the memory system, which reduces their versatility as the memory system.

On the other hand, the memory system 10A includes the memory controller 50A capable of adjusting the ratio between the current ICCQNA2 supplied to the third voltage line 21A by a first voltage generation circuit 52A and the current ICCQNA1 supplied to the third voltage line 21A by a third voltage generation circuit 62A, and the plurality of semiconductor memory devices 60A (60A-1 to 60A-k). Therefore, the ratio between the current ICCQNA2 and the current ICCQNA1 can be adjusted after design. As a result, an internal circuit 66A of the plurality of semiconductor memory devices 60A (60A-1 to 60A-k) receives a current in which the ratio between the current ICCQNA2 and the current ICCQNA1 is adjusted. Therefore, the memory system 10A is able to adjust the current according to the specifications and applications of the memory system 10A and has high versatility as the memory system.

### 2-2. Configuration of Memory Controller 50A

For example, similar to the memory controller 50, the memory controller 50A transmits a command CMD according to a program necessary for the operation of the semiconductor memory device 60A to the semiconductor memory device 60A. In addition, the memory controller 50A transmits the command CMD, the control signal, and the like according to the program to the semiconductor memory device 60A, and controls the data read operation from the semiconductor memory device 60A, the data write operation to the semiconductor memory device 60A, and the data erase operation of the semiconductor memory device 60A. In addition, the memory controller 50A is electrically connected to the semiconductor memory device 60A, and is configured to adjust the ratio between the current ICCQNA2 corresponding to the voltage VCCQN, that is supplied to the third voltage line 21A and the current ICCQAN1 corresponding to the voltage VCCQN, that is supplied to the third voltage line 21A.

As described in “1-2. Example of circuit configuration of semiconductor memory device 60”, respective signals such as the chip enable signal CEn, the command latch enable signal CLE, the address latch enable signal ALE, the write enable signal WEn, the read enable signal REn, and the signals DQ0 to DQ7 are transmitted and received between the memory controller 50A and the semiconductor memory device 60A. The respective signals such as the chip enable signal CEn, the command latch enable signal CLE, the address latch enable signal ALE, the write enable signal WEn, the read enable signal REn, and the signals DQ0 to DQ7 have the functions and configurations described in the first embodiment.

As illustrated in FIG. 6 or FIG. 7, the memory controller 50A includes a power supply circuit 510A, an internal circuit 56A, and a first interface circuit 58A. In addition, the memory controller 50A includes the first voltage line 20A, the second voltage line 30A, a portion of the third voltage line 21A, a portion of the fourth voltage line 31A, and a portion of the reference voltage line 40A.

For example, the power supply circuit 510A includes the first voltage generation circuit 52A and a second voltage generation circuit 54A.

The first voltage generation circuit 52A is electrically connected to the first voltage line 20A, the third voltage line 21A and the reference voltage line 40A. For example, the first voltage generation circuit 52A is electrically connected to the second voltage generation circuit 54A, the third voltage generation circuit 62A, and the internal circuit 66A. The first voltage generation circuit 52A is configured to generate the voltage VCCQN and the current ICCQNA2 corresponding to the voltage VCCQN, using the voltage VCC and the voltage VSS. The first voltage generation circuit 52A supplies the voltage VCCQN and the current ICCQNA2 to the third voltage line 21A and the internal circuit 66A.

The second voltage generation circuit 54A is electrically connected to the second voltage line 30A, the fourth voltage line 31A, and the reference voltage line 40A. In addition, for example, the second voltage generation circuit 54A is electrically connected to the first interface circuit 58A and a second interface circuit 68A. The second voltage generation circuit 54A is configured to generate the voltage VCCQL and the current ICCQLA corresponding to the voltage VCCQL, using the voltage VCCQ and the voltage VSS. The second voltage generation circuit 54A supplies the voltage VCCQL and the current ICCQLA to the fourth voltage line 31A. The second voltage generation circuit 54A supplies the current ICCQLA1 corresponding to the voltage VCCQN to the first interface circuit 58A, and supplies the current ICCQLA2 corresponding to the voltage VCCQN to the second interface circuit 68A.

For example, as illustrated in FIG. 7, the internal circuit 56A has a similar configuration to the internal circuit 56 described in the first embodiment. That is, the internal circuit 56A includes the RAM 520, the ROM 522, the ECC circuit 523, the processor 521, the buffer memory 524, and the internal bus 525. The RAM 520, the ECC circuit 523, the processor 521, the buffer memory 524, and the internal bus 525 have similar configurations and functions to the respective elements described in the first embodiment.

The first interface circuit 58A has a similar configuration and function to the first interface circuit 58 described in the first embodiment.

Although the illustration is omitted, for example, similar to the memory system 10, the memory system 10A may include a host interface for outputting requests (requests, instructions), data (e.g., write data), and the like received from the host to the internal bus 525. Further, for example, the host interface may transmit data (read data) from the semiconductor memory device 60A, signals including responses from the processor 521, and the like to the host. The host interface is electrically connected to the host. For example, similar to the host interface of the memory system 10, the host interface of the memory system 10A may be configured based on the UFS standards.

For example, the ROM 522 includes the first area 526 storing the first set value for setting the activation or deactivation of the first voltage generation circuit 52A and the third voltage generation circuit 62A, the second area 527 storing a plurality of second set values for setting the ratio between the current ICCQNA1 supplied to the third voltage line 21A and the current ICCQNA2 supplied to the third voltage line 21A, the third area 528 storing a plurality of third set values for setting at least one semiconductor memory device 60A to be used among the plurality of semiconductor memory devices 60A, the fourth area 529 storing a plurality of fourth set values for setting at least one memory cell array 630 to be used or at least one block BLK to be used in the memory unit 64A of at least one semiconductor memory device 60A to be used, the fifth area 530 storing a fifth set value for setting the value of current to be consumed by the semiconductor memory device 60A (current consumption value), setting the activation or deactivation of the first voltage generation circuit 52A and the third voltage generation circuit 62A, and adjusting the ratio between the current ICCQNA1 supplied to the third voltage line 21A and the current ICCQNA2 supplied to the third voltage line 21A according to the operation state of the memory system 10A or the semiconductor memory device 60A, and the sixth area 531 storing values corresponding to each command used by the processor 521.

Here, the operation of the memory controller 50A will be briefly described.

For example, similar to the memory controller 50, when the memory controller 50A receives a write request from the host, the memory controller 50A is operated as follows. The processor 521 temporarily stores data as the write target in the RAM 520. The processor 521 reads the data stored in the RAM 520 and inputs the read data to the ECC circuit 523. The ECC circuit 523 encodes the input data and inputs the codeword to the first interface circuit 58A. The first interface circuit 58A writes the input codeword to the semiconductor memory device 60A.

For example, when the memory controller 50A receives a read request from the host, the memory controller 50A is operated as follows. The first interface circuit 58A inputs the codeword read from the semiconductor memory device 60A to the ECC circuit 523. The ECC circuit 523 decodes the input codeword and stores the decoded data in the RAM 520. The processor 521 transmits the data stored in the RAM 520 to the host via the host interface.

### 2-3. Overview of Semiconductor Memory Device 60A

As illustrated in FIGS. 6 and 7, the semiconductor memory device 60A includes the third voltage generation circuit 62A, the memory unit 64A, the second interface circuit 68A, and the internal circuit 66A. In addition, the semiconductor memory device 60A includes a portion of the first voltage line 20A to which the voltage VCC is supplied, the third voltage line 21A to which the voltage VCCQN and the current ICCQNA1 corresponding to the voltage VCCQN are supplied, the fourth voltage line 31A to which the voltage VCCQL and the current ICCQLA2 corresponding to the voltage VCCQL are supplied, and a portion of the reference voltage line 40A to which a voltage VSS serving as a reference voltage is supplied, and is electrically connected to the first voltage line 20A, the second voltage line 30A, the fourth voltage line 31A, and the voltage VSS serving as the reference voltage.

The third voltage generation circuit 62A is electrically connected to the memory unit 64A, the first voltage line 20A, the third voltage line 21A, and the reference voltage line 40A. The third voltage generation circuit 62A is configured to receive the voltage VCC and the current ICCA1 to generate the voltage VCCQN and the current ICCQNA1 corresponding to the voltage VCCQN.

The memory unit 64A is electrically connected to the internal circuit 66A, the first voltage line 20A, and the reference voltage line 40A, and receives the voltage VCC and the current ICCA2 corresponding to the voltage VCC.

The second interface circuit 68A is electrically connected to the first interface circuit 58A, the second voltage generation circuit 54A, the internal circuit 66A, the fourth voltage line 31A, and the reference voltage line 40A. The second interface circuit 68A receives the voltage VCCQL and the current ICCQLA2 corresponding to the voltage VCCQL. In addition, the second interface circuit 68A may be configured based on similar interface specification to the second interface circuit 68.

The internal circuit 66A is electrically connected to the third voltage line 21A and the reference voltage line 40A. In addition, the internal circuit 66A receives the current ICCQNA1 corresponding to the voltage VCCQN and the current ICCQNA2 corresponding to the voltage VCCQN.

### 2-4. Example of Circuit Configuration of Semiconductor Memory Device 60A

As illustrated in FIG. 7, the semiconductor memory device 60A includes the third voltage generation circuit 62A, the second interface circuit 68A, a power supply circuit 610A, the internal circuit 66A, and the memory unit 64A.

The second interface circuit 68A has a similar configuration and function to the second interface circuit 68 described in the first embodiment.

For example, the power supply circuit 610A generates the voltage VCCQN using the third voltage generation circuit 62A, generates the voltage VCCQN necessary for write operation, read operation, and erase operation in accordance with the control of the sequencer 621, and supplies the generated voltage to the internal circuit 66A, the memory cell array 630, the row decoder 631, the column decoder 633, the sense amplifier module 632, and the like. For example, the row decoder 631 and the sense amplifier module 632 may supply the voltage supplied from the power supply circuit 610A to each memory cell in the memory cell array 630.

For example, the internal circuit 66A has a similar configuration and function to the internal circuit 66 described in the first embodiment. That is, the internal circuit 66A includes the buffer memory 620 and the sequencer 621. The buffer memory 620 and the sequencer 621 have similar configurations and functions to the respective elements described in the first embodiment.

The memory unit 64A has a similar configuration and function to the memory unit 64 described in the first embodiment. That is, the memory unit 64A includes the memory cell array 630, the row decoder 631, the sense amplifier module 632, and the column decoder 633. The memory cell array 630, the row decoder 631, the sense amplifier module 632, and the column decoder 633 have similar configurations and functions to the respective elements described in the first embodiment.

### 2-5. Example of Method of Operating Memory System 10A

Similar to the method of operating the memory system 10, the memory system 10A is operated using a flowchart similar to the flowchart of the memory system 10 illustrated in FIG. 4. As illustrated in FIG. 4, the method of operating the memory system 10A includes S10 to S20. The method of operating the memory system 10A is applicable to when the memory system 10 described in “1-6. Example of method of operating Memory System 10” is replaced with the memory system 10A. The method of operating the memory system 10A may be appropriately modified according to the configurations described in “2-1. Overview of memory system 10A” and “2-4. Example of circuit configuration of semiconductor memory device 60A”.

When the operation of the memory system 10A starts, S10 is executed. S10 is a step of supplying power to the memory system 10A. For example, an external device such as the host supplies power to the memory system 10A. The voltage VCC, a current ICCA3 corresponding to the voltage VCC, and the current ICCA1 corresponding to the voltage VCC are supplied to the first voltage line 20A, the voltage VCCQ, the current ICCQA1 corresponding to the voltage VCCQ, and the current ICCQA2 corresponding to the voltage VCCQ are supplied to the second voltage line 30A, and the voltage VSS is supplied to the reference voltage line 40A.

S11, S12 and S13 in the method of operating the memory system 10A are similar to S11, S12 and S13 in the method of operating the memory system 10.

After the process of S13, the memory system 10A executes the process of S14 and the process of S15 in parallel.

For example, S14 is a step of verifying whether a set value for activating the voltage generation circuit is read out and verifying whether to change the current ratio. In S14, the processor 521 verifies whether the first set value read from the first area 526 of the ROM 522 is a set value for activating the first voltage generation circuit 52A and the third voltage generation circuit 62A, and verifies whether the second set value read from the second area 527 of the ROM 522 is a set value that includes the ratio between the current ICCQNA2 and the current ICCQNA1.

As a result of the verification in S14 by the processor 521, when the first set value is the set value for activating the first voltage generation circuit 52A and the third voltage generation circuit 62A and the second set value is the set value that includes the ratio between the current ICCQNA2 and the current ICCQNA1 (YES in S14), the processor 521 executes the process of step 16. As a result of the verification in S14 by the processor 521, when the first set value is a set value for not activating the third voltage generation circuit 62A (NO in S14), the processor 521 executes the process of S17.

In addition, for example, in S14, the processor 521 may verify whether the fifth set value read from the fifth area 530 of the ROM 522 is a set value for setting a value of current consumed by the semiconductor memory device 60A (current consumption value), for setting the activation or deactivation of the first voltage generation circuit 52A and the third voltage generation circuit 62A, and for adjusting the ratio between the current ICCQNA2 supplied to the third voltage line 21A and the current ICCQNA1 supplied to the third voltage line 21A. Further, the fifth set value is a set value corresponding to the operation state of the memory system 10A or the semiconductor memory device 60A. In addition, for example, as a result of the verification in S14 by the processor 521, when the fifth set value is set (NO in S14), the processor 521 executes the process of S17.

For example, S15 is a step of verifying whether the set value related to the configuration of the semiconductor memory device 60A is read and whether to change the current ratio. Here, the configuration of the semiconductor memory device 60A is similar to configurations 1 to 3 of the semiconductor memory device 60 according to the first embodiment.

For example, in S15, the processor 521 verifies whether the first set value read from the first area 526 of the ROM 522 is the set value for activating the first voltage generation circuit 52A and the third voltage generation circuit 62A, verifies whether the second set value read from the second area 527 of the ROM 522 is the set value that includes the ratio between the current ICCQNA2 and the current ICCQNA1, and verifies whether the third set value read from the third area 528 of the ROM 522 is the set value for setting at least one semiconductor memory device to be used among the plurality of semiconductor memory devices 60A-1 to 60A-k. In addition, in S15, the processor 521 may verify whether the first set value read from the first area 526 of the ROM 522 is the set value for activating the first voltage generation circuit 52A and the third voltage generation circuit 62A, verify whether the second set value read from the second area 527 of the ROM 522 is the set value that includes the ratio between the current ICCQNA2 and the current ICCQNA1, verify whether the third set value read from the third area 528 of the ROM 522 is the set value for setting at least one semiconductor memory device to be used among the plurality of semiconductor memory devices 60A-1 to 60A-k, and verify whether the fourth set value read from the fourth area 529 of the ROM 522 is the set value for setting at least one memory cell array 630 to be used or at least one block BLK to be used in the memory unit 64A of the at least one semiconductor memory device to be used that is set by the third set value. It is to be noted that the first set value and the second set value in S15 are set values according to the configuration of the semiconductor memory device 60A.

For example, as a result of the verification by the processor 521, when the first set value is the set value for activating the first voltage generation circuit 52A and the third voltage generation circuit 62A, the second set value is the set value that includes the ratio between the current ICCQNA2 and the current ICCQNA1, and the third set value is the set value for setting at least one semiconductor memory device to be used among the plurality of semiconductor memory devices 60A-1 to 60A-k (YES in S15), the processor 521 executes the process of S16. For example, as a result of the verification by the processor 521, when the first set value is the set value for activating the first voltage generation circuit 52A and the third voltage generation circuit 62A, the second set value is the set value that includes the ratio between the current ICCQNA2 and the current ICCQNA1, the third set value is the set value for setting at least one semiconductor memory device to be used among the plurality of semiconductor memory devices 60A-1 to 60A-k, and the fourth set value is the set value for setting at least one memory cell array 630 to be used or at least one block BLK to be used in the memory unit 64A of the at least one semiconductor memory device to be used that is set by the third set value (YES in S15), the processor 521 executes the process of S16. As a result of the verification by the processor 521, when the third set value is the set value that does not set at least one semiconductor memory device to be used among the plurality of semiconductor memory devices 60A-1 to 60A-k (NO in S15), the processor 521 executes the process of S17. It is to be noted that when the third set value is not set, the fourth set value is not set either.

S16 is a step of changing the current ratio.

For example, when S16 is based on the first set value and the second set value set in S14, in S16, the processor 521 changes the ratio between the current ICCQNA2 and the current ICCQNA1 based on the first set value and second set value set in S14. For example, when the first set value is the set value for activating the first voltage generation circuit 52A and the third voltage generation circuit 62A, and the second set value is the set value for setting the ratio between the current ICCQNA1 and the current ICCQNA2 to X:Y, the processor 521 reads and loads into the RAM 520 a ninth program, from among the plurality of programs stored in the sixth area 531, which includes activating (using) the first voltage generation circuit 52A and the third voltage generation circuit 62A and setting the ratio between the current ICCQNA1 and the current ICCQNA2 to X:Y, and generates a ninth command based on the ninth program. The numerical values X and Y are expressed as percentages such that X+Y=100%, and any numerical value may be used as long as X+Y=100%. The second area 527 in the ROM 522 stores a plurality of second set values such that X+Y=100%. For example, when X is 50%, Y is 50%, and when X is 20%, Y is 80%.

In addition, for example, when S16 is based on the first set value and the second set value set in S15, in S16, the processor 521 changes the ratio between the current ICCQNA2 and the current ICCQNA1 based on the first set value, the second set value, and the third set value set in S15, or based on the first set value, the second set value, the third set value, and the fourth set value set in S15. For example, the first set value and the second set value set in S15 are similar to the first set value and the second set value “when S16 is based on the first set value and the second set value set in S14”. For example, the third set value is the set value for setting at least one semiconductor memory device to be used among the plurality of semiconductor memory devices 60A-1 to 60A-k, and the fourth set value is the set value for setting at least one memory cell array 630 to be used or at least one block BLK to be used in the memory unit 64A of the at least one semiconductor memory device to be used that is set by the third set value. For example, the processor 521 reads and loads into the RAM 520 a tenth program, from among the plurality of programs stored in the sixth area 531, which includes activating (using) the first voltage generation circuit 52A and the third voltage generation circuit 62A, setting the ratio between the current ICCQNA1 and the current ICCQNA2 to X:Y, and selecting at least one semiconductor memory device to be used from among the plurality of semiconductor memory devices 60A-1 to 60A-k, and generates a tenth command based on the tenth program. Further, for example, the processor 521 reads and loads into the RAM 520 an eleventh program from among the plurality of programs stored in the sixth area 531, which includes activating (using) the first voltage generation circuit 52A and the third voltage generation circuit 62A, setting the ratio between the current ICCQNA1 and the current ICCQNA2 to X:Y, selecting at least one semiconductor memory device to be used from among the plurality of semiconductor memory devices 60A-1 to 60A-k, and selecting at least one memory cell array 630 to be used or at least one block BLK to be used in the memory unit 64A of at least one semiconductor memory device to be used, and generates an eleventh command based on the eleventh program.

S17 is a step of transmitting a command.

For example, when the memory system 10A executes the processes of S14 and S16, and when the memory system 10A executes the processes of S15 and S16, in S17, the processor 521 transmits the data temporarily stored in the buffer memory 524, the address signal, the command generated in S16 (e.g., the ninth command, the tenth command or the eleventh command), and various control signals to the first interface circuit 58A via the internal bus 525, and the first interface circuit 58A transmits the data, the address signal, the ninth command, the tenth command, or the eleventh command, and the various control signals to the semiconductor memory device 60A (in particular, the second interface circuit 68A).

In addition, for example, when the memory system 10A executes the processes according to NO in S14, in S17, the first set value is the set value that includes that the first voltage generation circuit 52A and the third voltage generation circuit 62A are not activated, and the second set value is the set value that includes that the ratio between the current ICCQNA2 and the current ICCQNA1 is 1:0 (100% and 0%). That is, the current ICCQA2 accounts for 100% of the ratio. At this time, the processor 521 reads and loads into the RAM 520 a twelfth program that includes that the first voltage generation circuit 52A and the third voltage generation circuit 62A are not activated and that the current ICCQNA2 accounts for 100% of the ratio, and generates a twelfth command based on the twelfth program. The processor 521 transmits the data, the address signal, the command (e.g., the twelfth command), and various control signals temporarily stored in the buffer memory 524 to the first interface circuit 58A via the internal bus 525, and the first interface circuit 58A transmits the data, the address signal, the twelfth command, and the various control signals to the semiconductor memory device 60A (in particular, the second interface circuit 68A).

In addition, for example, in S17, when the memory system 10A executes the processes according to NO in S14, the processor 521 reads and loads into the RAM 520 a thirteenth program based on the fifth set value, and generates a thirteenth command based on the thirteenth program. The processor 521 transmits the data, the address signal, the command (e.g., the thirteenth command), and various control signals temporarily stored in the buffer memory 524 to the first interface circuit 58A via the internal bus 525, and the first interface circuit 58A transmits the data, the address signal, the fifth command, and the various control signals to the semiconductor memory device 60A (in particular, the second interface circuit 68A).

In addition, for example, in S17, when the memory system 10A executes the processes according to NO in S15, the processor 521 reads and loads into the RAM 520 a sixth program that includes not setting at least one semiconductor memory device to be used among the plurality of semiconductor memory devices 60A-1 to 60A-k, and generates a fourteenth command based on the fourteenth program. The processor 521 transmits the data, the address signal, the command (e.g., the fourteenth command), and various control signals temporarily stored in the buffer memory 524 to the first interface circuit 58A via the internal bus 525, and the first interface circuit 58A transmits the data, the address signal, the fourteenth command, and the various control signals to the semiconductor memory device 60A (in particular, the second interface circuit 68A).

After the processes of S17, the memory system 10A executes the process of S18 and the process of S19 in parallel.

In S18 and S19, the second interface circuit 68A executes a similar process to the second interface circuit 68 in the first embodiment.

For example, S18 is a similar step to S18 in the first embodiment.

For example, when the second interface circuit 68A receives one of the ninth command, the tenth command, or the eleventh command, the sequencer 621 verifies (determines) that the command is a command to activate the voltage generation circuit, activates the first voltage generation circuit 52A and the third voltage generation circuit 62A based on the command, and controls the semiconductor memory device 60A so that the semiconductor memory device 60A is operated at the set ratio between the current ICCQNA2 and the current ICCQNA1. In addition, when the second interface circuit 68A receives one of the ninth command, the tenth command, and the eleventh command (YES in S18), the memory system 10A repeatedly executes S16, S17 and S18.

In addition, for example, when the second interface circuit 68A receives one of the twelfth command or the fourteenth command, the sequencer 621 executes the process of S20 when it verifies (determines) that the command is not a command to activate the voltage generation circuit (NO in S18).

For example, S19 is a similar step to S19 in the first embodiment.

For example, when the second interface circuit 68A receives the thirteenth command, the sequencer 621 verifies (determines) that the thirteenth command is a command related to the operation state of the semiconductor memory device 60A (YES in S19), and the memory system 10A controls so that the processes of S16, S17, and S18 are executed. For example, in S19, the sequencer 621 detects a value of current consumed by the semiconductor memory device 60A based on the thirteenth command, sets the activation or deactivation of the first voltage generation circuit 52A and the third voltage generation circuit 62A according to the detected current value, and stores the detected current value in the buffer memory 620 so as to adjust the ratio between the current ICCQNA2 and the current ICCQNA1. In S16 following S19, the sequencer 621 reads the current value stored in the buffer memory 620, and transmits the read value to the memory controller 50A (in particular, the first interface circuit 58A) via the second interface circuit 68A. Further, in S16 following S19, the first interface circuit 58A receives the current value and stores the current value in the buffer memory 524 via the internal bus 525. For example, the processor 521 reads the current value based on the thirteenth command from the buffer memory 524 into the RAM 520, and by referring to the table in the RAM 520, reads, from the second area 527 in the ROM 520 into the buffer memory 524, the first set value for setting the activation or deactivation of the first voltage generation circuit 52A and the third voltage generation circuit 62A according to the current value, and the second set value corresponding to the ratio between the current ICCQNA2 and the current ICCQNA1. At this time, the processor 521 may read the third set value or the fourth set value from the third area 528 or the fourth area 529 into the buffer memory 524. In addition, for example, in S16 following S19, the processor 521 reads and loads into the RAM 520 a fifteenth program from among the plurality of programs stored in the sixth area 531, which includes activating (using) the first voltage generation circuit 52A and the third voltage generation circuit 62A, setting the ratio between the current ICCQNA2 and the current ICCQNA1 to X:Y, setting the activation or deactivation of the first voltage generation circuit 52A and the third voltage generation circuit 62A, and adjusting the ratio between the current ICCQNA2 and the current ICCQNA1, and generates a fifteenth command based on the fifteenth program. At this time, when the third set value or the fourth set value is stored in the buffer memory 524, the processor 521 may read and load into the RAM 520 a sixteenth program that incorporates a program based on the third set value or the fourth set value into the contents of the seventh program, and may generate a sixteenth command based on the sixteenth program. In addition, for example, in S17 following S19 and S16, the processor 521 transmits the data, the address signal, the seventh command, and various control signals temporarily stored in the buffer memory 524 to the first interface circuit 58A via the internal bus 525, and the first interface circuit 58A transmits the data, the address signal, the command (e.g., the fifteenth command or the sixteenth command), and the various control signals to the semiconductor memory device 60A (in particular, the second interface circuit 68A). The fifteenth command or the sixteenth command is a command based on the first set value and the second set value, and in S18 which follows S19, S16 and S17, the second interface circuit 68A receives the fifteenth command or the sixteenth command, and the sequencer 621 verifies (determines) that the fifteenth command or the sixteenth command is a command to activate the voltage generation circuit, activates or deactivates the first voltage generation circuit 52A and the third voltage generation circuit 62A based on the fifteenth command, adjusts the ratio between the current ICCQNA2 and the current ICCQNA1 to the ratio between the current ICCQNA2 and the current ICCQNA1 set in the fifteenth command, and controls the semiconductor memory device 60A so that the semiconductor memory device 60A is operated accordingly.

In S19, when verifying (determining) that the command received by the sequencer 621 is not a command related to the operation state of the semiconductor memory device 60A (NO in S19), the sequencer 621 executes the process of S20.

S20 is a step of executing a normal operation. If NO in S18 and S19, the sequencer 621 controls the semiconductor memory device 60A to be operated normally. For example, the normal operation is an operation in which the first voltage generation circuit 52A and the third voltage generation circuit 62A are deactivated and not used, and the current ICCQNA2 corresponding to the voltage VCCQN generated by the first voltage generation circuit 52A is supplied to the internal circuit 66A.

For example, the memory system 10A is configured to set the ratio between the current ICCQNA2 and the current ICCQNA1 supplied to the third voltage line 21A in accordance with the first set value to the fifth set value, using the method of operating described in “2-5. Example of method of operating memory system 10A”. Furthermore, for example, the memory system 10A is configured to adjust the ratio between the current ICCQNA2 and the current ICCQNA1 supplied to the third voltage line 21A according to the configuration of the semiconductor memory device 60A or the operation state of the semiconductor memory device 60A, using the method of operating described in “2-5. Example of method of operating memory system 10A”. Therefore, the memory system 10A is able to adjust the current according to the specifications and applications of the memory system 10A and has high versatility as the memory system 10A.

### 2-6. Modification of Memory System 10A

FIG. 8 is a plan view illustrating a system according to a modification of the memory system 10A including the semiconductor memory device 60A. For example, the system according to the modification of the memory system 10A including the semiconductor memory device 60A will be referred to as a modified memory system 10A. The modified memory system 10A includes a plurality of sets of semiconductor memory devices 60A, with the plurality of semiconductor memory devices 60A-1 to 60A-k in the memory system 10A being one set of semiconductor memory devices 60A. The other configurations and functions of the modified memory system 10A are similar to the configurations and functions of the memory system 10A. Therefore, in “2-6. Modification of memory system 10A”, contents related to the plurality of sets of semiconductor memory devices 60A will be primarily described, and description of contents identical or similar to the configurations and functions of the memory system 10A may be omitted.

As illustrated in FIG. 8, the modified memory system 10A includes a configuration in which the first interface circuit 58A in the memory controller 50A is electrically connected to the plurality of sets of semiconductor memory devices 60A to transmit and receive data to and from the plurality of sets of semiconductor memory devices 60A.

For example, similar to the first interface circuit 58 according to the first embodiment, the first interface circuit 58A includes the plurality of channels CH0 to CHn (where, n is a positive integer). Each of the plurality of sets of semiconductor memory devices 60A is electrically connected to each channel. In the modified memory system 10A illustrated in FIG. 8, the plurality of sets of semiconductor memory devices 60A are connected to each of channels CH0 and CH1, and illustration of electrical connection between the channels CH2 to CHn and the plurality of sets of semiconductor memory devices 60A is omitted.

For example, when operating the modified memory system 10A, the third set value includes a set value for at least one channel from among the plurality of channels CH0 to CHn, and one semiconductor memory device 60A in the at least one channel. At least one channel and at least one semiconductor memory device 60A to be used are selected in accordance with the third set value, and processes such as writing the data, reading the data and erasing the data are executed on the selected semiconductor memory device 60A.

For example, the write operation and the read operation of the modified memory system 10A are similar to the write operation and the read operation of the modified memory system 10 according to the first embodiment.

Similar to the method of operating the memory system 10A, the modified memory system 10A is operated using a flowchart similar to the flowchart illustrated in FIG. 4. As illustrated in FIG. 4, similar to the method of operating the memory system 10A, the method of operating the modified memory system 10A includes steps S10 to S20. The method of operating the modified memory system 10A is applicable to when the memory system 10A in the operation described in “2-5. Example of method of operating memory system 10A” is replaced with the modified memory system 10A. It is to be noted that the method of operating the modified memory system 10A may be modified as appropriate in accordance with the configuration described in “2-6. Modification of memory system 10A”.

The configuration of the semiconductor memory device 60A in the modified memory system 10A may be illustrated as configurations 1 to 4, similar to the configuration of the semiconductor memory device 60 in the modified memory system 10. In addition, the operation state of the semiconductor memory device 60A in the modified memory system 10A may include the state of the plurality of sets of semiconductor memory devices 60A electrically connected to the plurality of channels CH0 to CHn, similar to the configuration of the semiconductor memory device 60 in the modified memory system 10, and the method of operating the modified memory system 10A may include controlling the ratio of current supplied to the plurality of sets of semiconductor memory devices 60A electrically connected to the plurality of channels CH0 to CHn.

### 2-7. Stabilization of Voltage of Memory System 10A

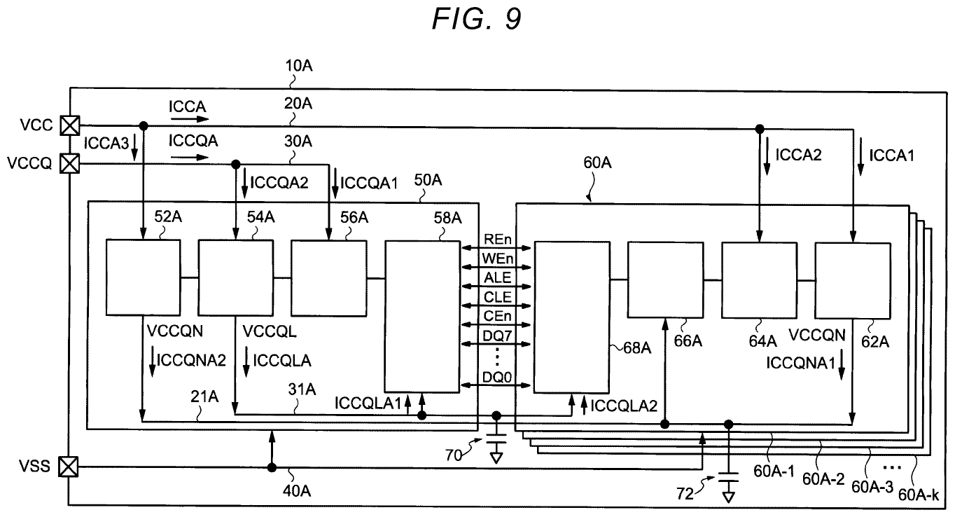

The voltage stabilization of the memory system 10A will be described with reference to FIG. 9. FIG. 9 is a plan view illustrating an example of the voltage stabilization of the memory system 10A.

For example, as illustrated in FIG. 9, the memory system 10A may include a capacitive element 70 and may include a capacitive element 72.

The capacitive element 70 is electrically connected to the fourth voltage line 31A. The capacitive element 70 can prevent dynamic voltage variations of the fourth voltage line 31A and stabilize the voltage VCCQL.

The capacitive element 72 is electrically connected to the third voltage line 21A. The capacitive element 72 can prevent dynamic voltage variations of the third voltage line 21A and stabilize the voltage VCCQN.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure. In addition, each embodiment described above can be properly combined as long as there is no conflict with each other, and technical matters common to the embodiments are included in the respective embodiments even if not explicitly stated.

Even if there are other effects and advantages different from those by the aspects of each of the embodiments described above, those that are clear from the description in this specification or that can be easily predicted by a person skilled in the art are naturally understood to be brought about by the present disclosure.

What is claimed is:

1. A semiconductor device comprising:
a first voltage line to which a first voltage is supplied;
a second voltage line to which a second voltage lower than the first voltage and a first current corresponding to the second voltage are supplied;
a third voltage line to which a third voltage and a second current corresponding to the third voltage are supplied;
a fourth voltage line to which a fourth voltage higher than the second voltage and lower than the first voltage is supplied;
a reference voltage line to which a reference voltage that is lower than the second voltage and that serves as a reference is supplied;
a first voltage generation circuit electrically connected to the first voltage line, the third voltage line, and the reference voltage line, and configured to generate the third voltage and the second current;
a second voltage generation circuit electrically connected to the first voltage line, the fourth voltage line, and the reference voltage line, and configured to generate the fourth voltage;
a memory unit electrically connected to the first voltage line and the reference voltage line;
an interface circuit electrically connected to the second voltage line, the third voltage line, and the reference voltage line; and
an internal circuit electrically connected to the fourth voltage line, the reference voltage line, the interface circuit, and the memory unit, wherein
the semiconductor device is electrically connected to a control circuit configured to adjust a ratio between the first current supplied to the second voltage line and the second current supplied to the third voltage line.

2. The semiconductor device according to claim 1, wherein the third voltage is the same as the second voltage.

3. The semiconductor device according to claim 1, wherein the interface circuit is configured based on Open NAND Flash Interface standards.

4. A memory system, comprising:
a plurality of semiconductor devices each including:
a first voltage line to which a first voltage is supplied;
a second voltage line to which a second voltage lower than the first voltage and a first current corresponding to the second voltage are supplied;
a third voltage line to which a third voltage and a second current corresponding to the third voltage are supplied;
a fourth voltage line to which a fourth voltage higher than the second voltage and lower than the first voltage is supplied;
a reference voltage line to which a reference voltage that is lower than the second voltage and that serves as a reference is supplied;
a first voltage generation circuit electrically connected to the first voltage line, the third voltage line, and the reference voltage line, and configured to generate the third voltage and the second current;
a second voltage generation circuit electrically connected to the first voltage line, the fourth voltage line, and the reference voltage line, and configured to generate the fourth voltage;
a memory unit electrically connected to the first voltage line and the reference voltage line;
an interface circuit electrically connected to the second voltage line, the third voltage line, and the reference voltage line; and
an internal circuit electrically connected to the fourth voltage line, the reference voltage line, the interface circuit, and the memory unit; and
a control circuit including a memory device storing a plurality of set values and a plurality of programs, and configured to adjust a ratio between the first current supplied to the second voltage line and the second current supplied to the third voltage line, wherein
the memory unit of each of the plurality of semiconductor devices includes a memory cell array including a plurality of blocks, and
the plurality of set values include a first set value for setting activation or deactivation of the first voltage generation circuit, a plurality of second set values for setting the ratio, a third set value for setting at least one semiconductor device to be used among the plurality of semiconductor devices, and a fourth set value for setting at least one block to be used in the memory unit of the at least one semiconductor device to be used.

5. The memory system according to claim 4, wherein the control circuit is configured to, after the first voltage, the second voltage, and the reference voltage are supplied, read the first set value and the second set value stored in the memory device, read a first program corresponding to the first set value and the second set value from among the plurality of programs, and transmit a first command based on the first program to the plurality of semiconductor devices.

6. The memory system according to claim 4, wherein the control circuit is configured to, after the first voltage, the second voltage, and the reference voltage are supplied, read the first set value, the second set value, and the third set value stored in the memory device, read a second program corresponding to the first set value, the second set value, and the third set value from among the plurality of programs, and transmit a second command based on the second program to the plurality of semiconductor devices.

7. The memory system according to claim 4, wherein the control circuit is configured to, after the first voltage, the second voltage, and the reference voltage are supplied, read the first set value, the second set value, the third set value, and the fourth set value stored in the memory device, read a third program corresponding to the first set value, the second set value, the third set value, and the fourth set value from among the plurality of programs, and transmit a third command based on the third program to the plurality of semiconductor devices.

8. The memory system according to claim 4, wherein
the plurality of set values include a fifth set value for setting a value of current consumed by the plurality of semiconductor memory devices, setting the activation or deactivation of the first voltage generation circuit, and adjusting the ratio, and
the control circuit is configured to, after the first voltage, the second voltage and the reference voltage are supplied, read a fourth program corresponding to the first set value, the second set value, and the fifth set value from among the plurality of programs, and transmit a fourth command based on the fourth program to the plurality of semiconductor devices.

9. The memory system according to claim 4, wherein
the control circuit includes an interface circuit different from the interface circuit of the semiconductor devices, and
the interface circuit of the control circuit is used for connection with a host and configured based on Universal Flash Storage standards.

10. A memory system, comprising:
a first voltage line to which a first voltage is supplied;
a second voltage line to which a second voltage lower than the first voltage is supplied;
a third voltage line to which a third voltage same as the second voltage is supplied;
a fourth voltage line to which a fourth voltage lower than the third voltage is supplied;
a reference voltage line to which a reference voltage that is lower than the fourth voltage and that serves as a reference is supplied;
a control circuit including:
a first voltage generation circuit electrically connected to the first voltage line, the third voltage line, and the reference voltage line, and configured to generate the third voltage and a first current corresponding to the third voltage;
a second voltage generation circuit electrically connected to the second voltage line, the fourth voltage line, and the reference voltage line, and configured to generate the fourth voltage;
a first internal circuit electrically connected to the second voltage line and the reference voltage line; and
a first interface circuit electrically connected to the fourth voltage line, the reference voltage line, and the first internal circuit; and
a semiconductor device including:
a third voltage generation circuit electrically connected to the first voltage line, the third voltage line, and the reference voltage line, and configured to generate the third voltage and a second current corresponding to the third voltage;
a memory unit electrically connected to the first voltage line and the reference voltage line;
a second internal circuit electrically connected to the third voltage line and the reference voltage line; and
a second interface circuit electrically connected to the fourth voltage line, the reference voltage line, the second internal circuit, and the first interface circuit, wherein
the control circuit is configured to adjust a ratio between the first current supplied from the first voltage generation circuit to the third voltage line and the second current supplied from the third voltage generation circuit to the third voltage line and the second internal circuit.

11. The memory system according to claim 10, comprising a plurality of the semiconductor devices, wherein
the memory unit of each of the plurality of semiconductor memory devices includes a memory cell array including a plurality of blocks,
the control circuit includes a memory device storing a plurality of set values and a plurality of programs, and
the plurality of set values include a first set value for setting activation or deactivation of the first voltage generation circuit and the third voltage generation circuit, a plurality of second set values for setting the ratio, a third set value for setting at least one semiconductor device to be used among the plurality of semiconductor devices, and a fourth set value for setting at least one block to be used in the memory unit of the at least one semiconductor device to be used.

12. The memory system according to claim 11, wherein the control circuit is configured to, after the first voltage, the second voltage, and the reference voltage are supplied, read the first set value and the second set value stored in the memory device, read a first program corresponding to the first set value and the second set value from among the plurality of programs, and transmit a first command based on the first program to the plurality of semiconductor memory devices.

13. The memory system according to claim 11, wherein the control circuit is configured to, after the first voltage, the second voltage, and the reference voltage are supplied, read the first set value, the second set value, and the third set value stored in the memory device, read a second program corresponding to the first set value, the second set value, and the third set value from among the plurality of programs, and transmit a second command based on the second program to the plurality of semiconductor devices.

14. The memory system according to claim 11, wherein the control circuit is configured to, after the first voltage, the second voltage, and the reference voltage are supplied, read the first set value, the second set value, the third set value, and the fourth set value stored in the ROM, read a third program corresponding to the first set value, the second set value, the third set value, and the fourth set value from among the plurality of programs, and transmit a third command based on the third program to the plurality of semiconductor devices.

15. The memory system according to claim 11, wherein
the plurality of set values include a fifth set value for setting a value of current consumed by the plurality of semiconductor devices, setting the activation or deactivation of the first voltage generation circuit and the third voltage generation circuit, and adjusting the ratio, and
the control circuit is configured to, after the first voltage, the second voltage and the reference voltage are supplied, read a fourth program corresponding to the first set value, the second set value, and the fifth set value from among the plurality of programs, and transmit a fourth command corresponding to the fourth program to the plurality of semiconductor memory devices.

16. The memory system according to claim 10, wherein the fourth voltage line is electrically connected to a capacitive element for stabilizing the fourth voltage.

17. The memory system according to claim 10, wherein the third voltage line is electrically connected to a capacitive element for stabilizing the third voltage.

18. The memory system according to claim 10, wherein the second interface circuit is configured based on Open NAND Flash Interface standards.

19. The memory system according to claim 10, wherein
the control circuit includes a third interface circuit different from the first interface circuit and the second interface circuit, and
the third interface circuit is used for connection with a host and is configured based on Universal Flash Storage standards.
